(19) United States
(12) Patent Application Publication
(10) Pub. No.: US 2026/0334301 A1
(43) Pub. Date: Oct. 22, 2026

(54) PACKAGE STRUCTURE INCLUDING A PACKAGE LID WITH A BOTTOM LID PORTION AND TOP LID PORTION AND METHODS FOR FORMING THE SAME

(71) Applicant: Taiwan Semiconductor Manufacturing Company Limited, Hsinchu (TW)

(72) Inventors: Wensen Hung, Zhubei City (TW); Yen-Fu Su, Hsinchu City (TW); Tsung-Yu Chen, Hsinchu City (TW)

(21) Appl. No.: 19/722,789

(22) Filed: Jun. 27, 2026

Related U.S. Application Data
(63) Continuation of application No. 18/823,882, filed on Sep. 4, 2024.

(51) Int. Cl. H10W 76/17; H05K 1/181; H10W 40/25; H10W 74/01; H10W 74/10; H10W 90/00; H10W 70/60; H10W 72/20; H10W 74/15; H10W 90/20

(52) U.S. Cl. CPC H10W 76/17; H05K 1/181; H10W 40/25; H10W 74/016; H10W 74/117; H10W 90/401; H10W 70/60; H10W 72/252; H10W 74/15; H10W 90/00; H10W 90/288; H10W 90/724; H10W 90/734

(57) ABSTRACT

A package structure includes a package substrate, a package module on the package substrate, an outer molding material layer on the package substrate around the package module, a thermal interface material (TIM) layer on the package module, and a package lid on the TIM layer and attached to the outer molding material layer. The package lid includes a bottom lid portion having a first coefficient of thermal expansion (CTE), and a top lid portion attached to the bottom lid portion and having a second CTE less than the first CTE.

### CROSS-REFERENCE TO RELATED APPLICATIONS

This application is a continuation of U.S. Application No. 18/823,882 entitled “Package Structure Including a Package Lid with a Bottom Lid Portion and Top Lid Portion and Methods for Forming the Same,” filed Sep. 4, 2024, which is incorporated herein by reference in its entirety for all purposes.

### BACKGROUND

A package structure may include a package underfill to fill a gap between a die and a substrate or interposer. Package underfill may provide mechanical support, enhance thermal conductivity, and improve the reliability of the package structure by reducing stress on solder joints during thermal cycling. The package underfill material may include an epoxy-based compound that is dispensed in liquid form and then cured to form a solid protective layer.

The package structure may also include a thermal interface material (TIM) layer to enhance thermal conductivity and facilitate heat transfer. The TIM layer may be located, for example, between a heat-generating component (like a microprocessor or graphical processing unit (GPU)) and a heat sink or spreader. The TIM layer may be made from various materials, including thermal grease, phase change materials, thermal pads, or even liquid metals. The TIM layer may fill microscopic air gaps and irregularities on the surfaces to ensure efficient thermal conduction, thereby maintaining optimal operating temperatures and preventing overheating.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a vertical cross-sectional view of a package module in the package structure according to one or more embodiments.

FIG. 1C is a plan view (e.g., top-down view) of the package structure according to one or more embodiments.

FIG. 2A is a schematic illustration of the package structure under a room temperature condition according to one or more embodiments.

FIG. 2B is a schematic illustration of the package structure under a high temperature condition according to one or more embodiments.

FIG. 2C is a schematic illustration of the package structure under a low temperature condition according to one or more embodiments.

FIG. 3A is a vertical cross-sectional view of an intermediate structure including the TIVs on a first carrier substrate (e.g., carrier wafer) according to an embodiment of the present invention.

FIG. 3B is a vertical cross-sectional view of an intermediate structure including the interconnect dies on the first carrier substrate 1 according to an embodiment of the present invention.

FIG. 3C is a vertical cross-sectional view of an intermediate structure including the lower molding material layer according to one or more embodiments.

FIG. 3D is a vertical cross-sectional view of an intermediate structure after polishing (e.g., planarizing) the lower molding material layer according to one or more embodiments.

FIG. 3E is a vertical cross-sectional view of an intermediate structure including the upper RDL structure according to one or more embodiments.

FIG. 3F is a vertical cross-sectional view of an intermediate structure including the semiconductor dies on the upper RDL structure according to one or more embodiments.

FIG. 3G is a vertical cross-sectional view of an intermediate structure including the package module underfill layer according to one or more embodiments.

FIG. 3H is a vertical cross-sectional view of an intermediate structure including the upper molding material layer according to one or more embodiments.

FIG. 3I is a vertical cross-sectional view of an intermediate structure after polishing (e.g., planarizing) the upper molding material layer according to one or more embodiments.

FIG. 3J is a vertical cross-sectional view of an intermediate structure including a second carrier substrate on the upper molded portion according to one or more embodiments.

FIG. 3K is a vertical cross-sectional view of an intermediate structure including the lower RDL structure according to one or more embodiments.

FIG. 3L is a vertical cross-sectional view of an intermediate structure on a frame mount according to one or more embodiments.

FIG. 3M is a vertical cross-sectional view of an intermediate structure after removing the second carrier substrate according to one or more embodiments.

FIG. 3N is a vertical cross-sectional view of an intermediate structure after remounting the intermediate structure on the frame mount according to one or more embodiments.

FIG. 3O is a vertical cross-sectional view of an intermediate structure including the package module on the package substrate according to one or more embodiments.

FIG. 3P is a vertical cross-sectional view of an intermediate structure including the package underfill layer according to one or more embodiments.

FIG. 3Q is a vertical cross-sectional view of an intermediate structure including the outer molding material layer according to one or more embodiments.

FIG. 3R is a vertical cross-sectional view of an intermediate structure including the TIM layer and adhesive layer according to one or more embodiments.

FIG. 3S is a vertical cross-sectional view of an intermediate structure including the package lid according to one or more embodiments.

FIG. 3T is a vertical cross-sectional view of an intermediate structure including the solder balls of the BGA according to one or more embodiments.

FIG. 4 is a flow chart illustrating a method of making the package structure according to one or more embodiments.

FIG. 5A is a vertical cross-sectional view of the package lid having a first alternative design according to one or more embodiments.

FIG. 5B is a vertical cross-sectional view of the package lid having a second alternative design according to one or more embodiments.

FIG. 6 is a perspective view of the package lid having a third alternative design according to one or more embodiments.

FIG. 7A is a perspective view of the top lid portion and the bottom lid portion prior to assembly according to one of more embodiments.

FIG. 7B is a perspective view of the top lid portion positioned over the bottom lid portion prior to assembly according to one of more embodiments.

FIG. 7C is a perspective view of the assembled package lid including the top lid portion and bottom lid portion prior to assembly according to one of more embodiments.

FIG. 8 is a vertical cross-sectional view of the package lid having a fourth alternative design according to one or more embodiments.

FIG. 9A is a vertical cross-sectional view of the package lid having a fifth alternative design according to one of more embodiments.

FIG. 9B is a vertical cross-sectional view of the package lid having a sixth alternative design according to one of more embodiments.

FIG. 9C is a vertical cross-sectional view of the package lid having a seventh alternative design according to one of more embodiments.

FIG. 10 is a vertical cross-sectional view of the package structure having a first alternative design according to one of more embodiments.

FIG. 11 is a vertical cross-sectional view of a semiconductor device 1 according to one of more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Package structures may sometimes experience delamination of the package underfill and bleeding of the TIM layer. Delamination of the package underfill may be caused, for example, by coefficient of thermal expansion (CTE) mismatch, moisture damage, contamination, inadequate curing of the package underfill and/or external mechanical stress. Bleeding of the TIM layer may be caused, for example, by thermal cycling, excessive pressure during assembly or operation, incompatibility with a surface on which the TIM layer is located, aging of the TIM layer and/or prolonged exposure to high temperatures.

In particular, thermal and mechanical stress in package structures (e.g., large semiconductor packages) may lead to underfill delamination (e.g., UF1 delamination) and bleeding of a metal TIM layer (e.g., metal TIM1) after ball mount/mass reflow (MR) (e.g., a high temperature condition). TIM bleeding may lead to poor coverage of TIM1 after package build (e.g., as determined by transparent scanning acoustic microscope (TSAM)) and an issue with poor thermal resistance (TR) (e.g., a high thermal resistance that may result in a poor thermal dissipation performance). In particular, a large chip-on-wafer (CoW) warp on a ring package may lead to high die crack and TIM layer (TIM 2) pump-out risk, a poor and unstable package performance due to large variation in TIM bond line thickness (BLT), and a poor package on-board yield.

It may be difficult to manage thermal and mechanical stress in large semiconductor packages (e.g., packages having a 5xTV1 type lid). Thermal and mechanical stress may be especially difficult to manage in large, lidded semiconductor packages including an interposer with one or more interconnect dies (e.g., local silicon interconnect (LSI) dies, local redistribution interconnect (LRI) dies) for die-to-die interconnect and redistribution layers (RDL layers) for power and signal delivery.

Tests have been performed on a package structure including a molded chip-on-wafer-on-substrate package with a package lid (e.g., a 5xTV1 type lid). The package structure included an interposer having a size of about 54 mm x 3.5 mm (5.4x). The package size (e.g., package area) was about 85 mm x 110 mm. The package lid included a 1 mm thick copper lid and the TIM layer had a thickness of about 200 µm. The package substrate build of materials (BOM) included a 9-2-9, 1.6 mm, 796GLH, GL 107. The package structure included frontside and backside redistribution layers (RDL layers) (e.g., 2xRDL frontside and 1xRDL backside). In such instances, testing revealed a room temperature mean package warpage (with BGA facing down) of about 168 µm, a high temperature mean package warpage (with BGA facing down) of about 122 µm and underfill (UF1) delamination at the system-on-chip (SoC)-high-bandwidth memory (HBM) gap of about 2.15 times.

One or more embodiments of the present disclosure may include a novel package lid (e.g., chip-on-wafer-on-substrate package lid) that may mitigate against issues including package underfill delamination and TIM (e.g., metal TIM) bleeding. At least one embodiment may include a package structure including a dual package lid (e.g., dual lid or dual lid structure). In at least one embodiment, the package structure may have a size in a range from about 80 mm x 80 mm to about 200 mm x 200 mm. The package structure may include, for example, a 2.5D stacked die structure, a 3D integrated circuit (3DIC) structure, an integrated fan-out LSI structure, etc.

The package lid may include a bottom lid portion having a high coefficient of thermal expansion (CTE) (e.g., at the TIM layer) and a top lid portion having a low CTE. The package lid may also include a bonding layer between the top lid portion and bottom lid portion and bonding the top lid portion to the bottom lid portion.

The package lid may help to generate a matching die warp effect in the package structure. The package lid may include a low CTE cavity on top of the package lid structure. In at least one embodiment, a heat sink may be attached to the package lid of the package structure. The package lid may also include a flattened package lid top surface that may effectively contact a system heat sink.

One or more embodiments of the package lid may provide several advantages to a package structure. The package lid may help manage thermal and mechanical stress in a package structure in a room temperature condition, high temperature condition and low temperature condition. Such conditions may occur, for example, during fabrication and/or testing of the package structure. A low temperature condition and high temperature condition may include, for example, a package reliability test condition, such as in temperature cycling tests for temperature cycling grading (TCG) where the temperature may range from about -40ºC to 125ºC.

In particular, the package lid may reduce a high temperature stress of package lid penetrating into underfill/molding compound (MC)/stacked SoC and local silicon interconnect (LSI) dies. The package lid may improve overall package coefficient of performance (COP) (e.g., improve surface mount technology (SMT) yield). The package lid may improve package thermal performance by reducing a variation of the bond line thickness (BLT) (e.g., reducing a thickness variation in the TIM layers) in a semiconductor device. The package lid may also help to inhibit die crack during heat sink (HS) mount and help to reduce TIM layer (e.g., TIM2) pumping out by providing a more flattened lid /heat sink contact surface) in the semiconductor device.

In at least one embodiment, the package lid may include a top lid having a low CTE in a range from about 1 to 10. In at least one embodiment, the top lid may be composed of one or more of Kovar, Invar, Co, Cu/Mo alloy, SiAl, AlN, AlSiN, AlSiC, CuSiC AgD (silver-diamond composite), CuD (copper-diamond composite), diamond substrate (e.g., diamond plate), Alloy42, etc. The package lid may include a bottom lid having a high CTE in a range from about 17 to 25. In at least one embodiment the bottom lid may be composed of one or more of Cu, Ag, Al, stainless steel, CuAg alloy, CuNi alloy, etc. The package lid may experience less TIM1 bleeding after MR, may have a low LSI crack stress, a better thermal performance (less TIM2 pump out), and a better SMT yield (less package warp).

In at least one embodiment, a top lid thickness and a bottom lid thickness may be selected to control a morphology of the package lid so as to match a die (e.g., CoW die or package module) warp profile. This may help to reduce thermal stress induced in the package lid at room temperature, high temperature and low temperature. In at least one embodiment, the top lid thickness (e.g., about 1.5 mm) may be greater than the bottom lid thickness (e.g., about 0.5 mm) to make the morphology of the package lid match the CoW die warp profile at room temperature, high temperature and low temperature. In at least one embodiment, the top lid thickness (e.g., about 1.0 mm) may be about the same as the bottom lid thickness (e.g., about 1.0 mm) to make the morphology of the package lid match the CoW die warp profile at room temperature, high temperature and low temperature. In at least one embodiment, the top lid thickness (e.g., about 0.5 mm) may be less than the bottom lid thickness (e.g., about 1.5 mm) to make the morphology of the package lid match the CoW die warp profile at room temperature, high temperature and low temperature.

In at least one embodiment, the top lid and/or the bottom lid may include a patterned surface which may help to control a local curvature of the package lid. In at least one embodiment, warpage of the package structure including warpage of the package substrate may be reduced. The patterned surface may include, for example, one or more projections, one or more recesses, etc. In at least one embodiment, a pattern of the top lid may have an interdigitated configuration with a pattern of the bottom lid. In at least one embodiment, the top lid may have a low stiffness pattern and the bottom lid may have a high stiffness pattern. In at least one embodiment, the top lid may have a medium stiffness pattern and the bottom lid may have a high stiffness pattern. In at least one embodiment, the top lid may have a high stiffness pattern and the bottom lid may have a low stiffness pattern, and so on.

In at least one embodiment, artificial intelligence (AI) may be used to generate a custom pattern to fit die warp at low temperature, room temperature and high temperature.

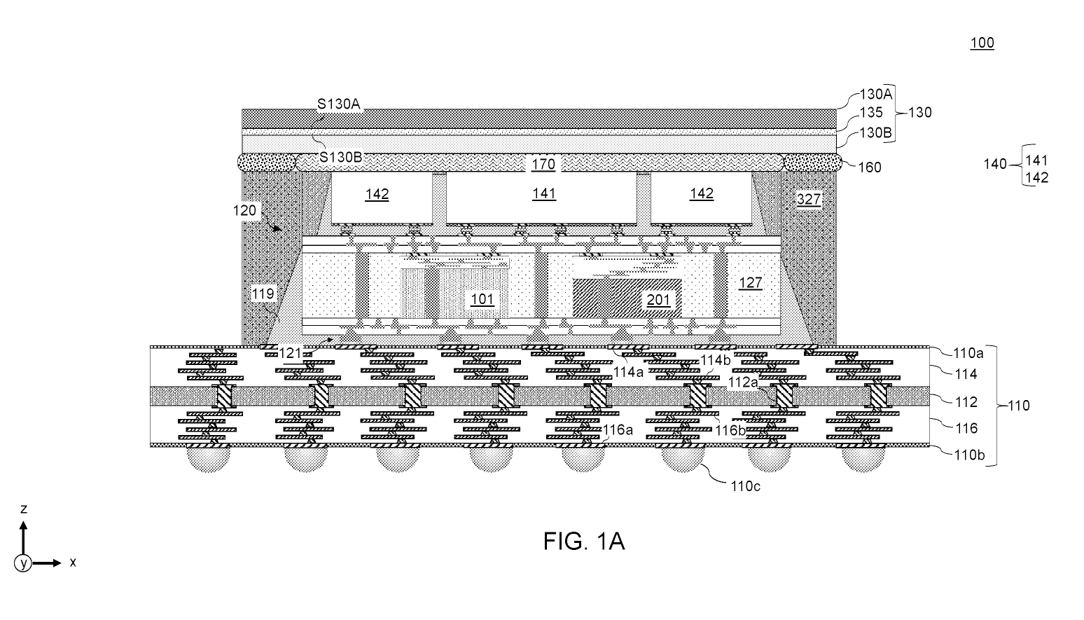

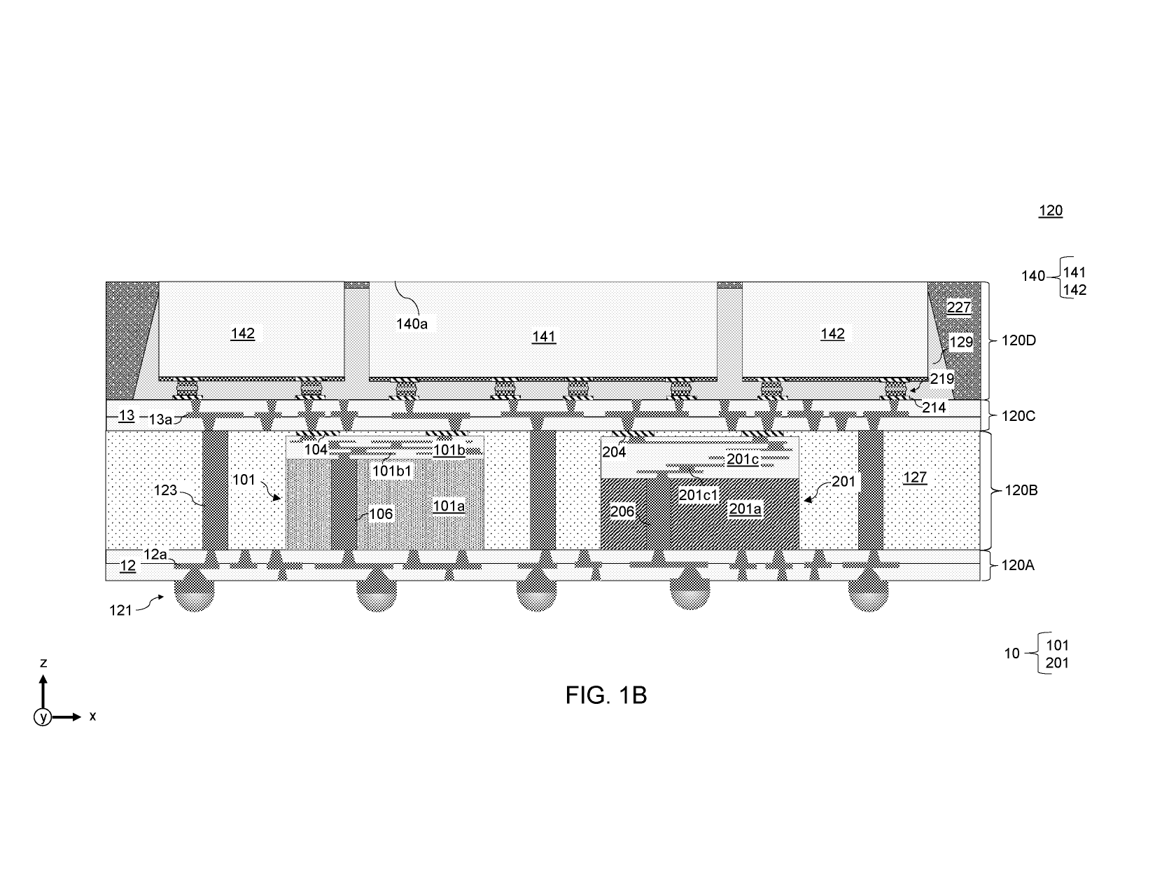

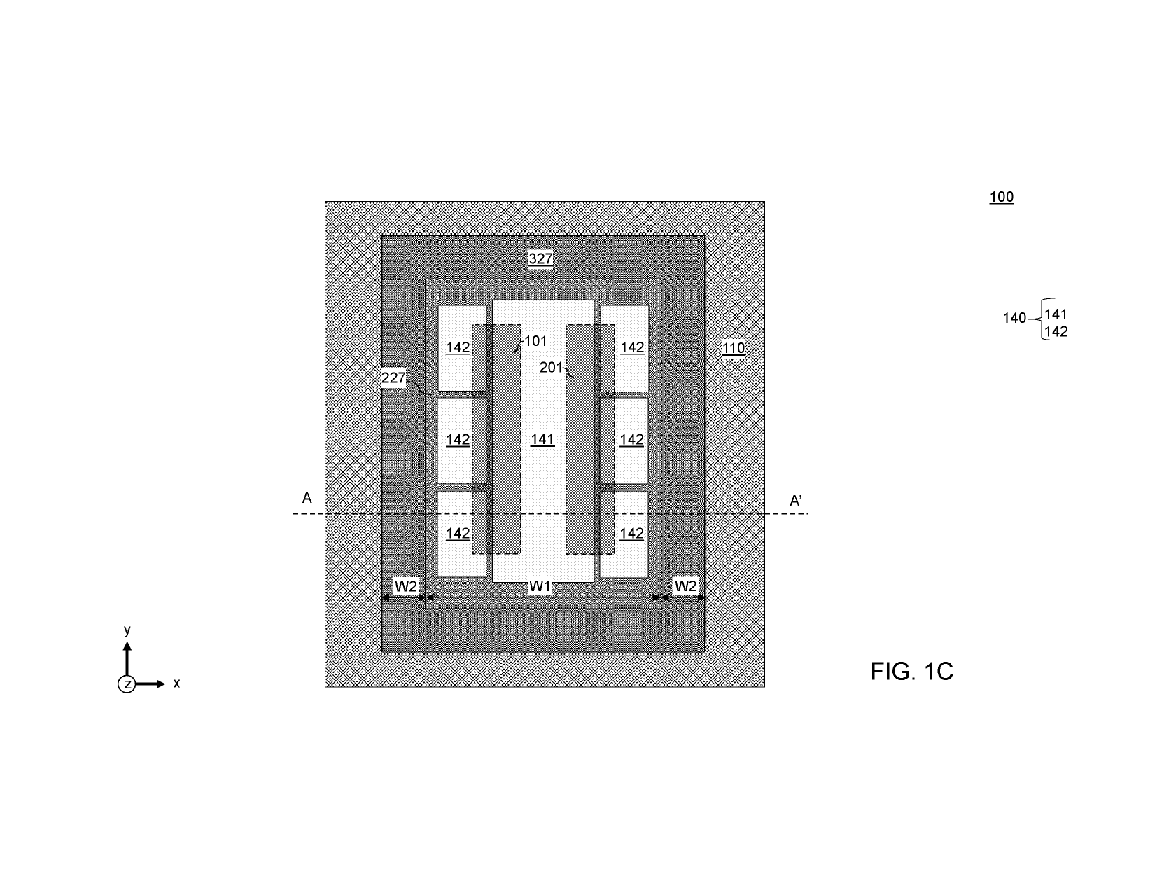

FIG. 1A is a vertical cross-sectional view of a package structure 100 according to one or more embodiments. FIG. 1B is a vertical cross-sectional view of a package module 120 in the package structure 100 according to one or more embodiments. FIG. 1C is a plan view (e.g., top-down view) of the package structure 100 according to one or more embodiments. The vertical cross-sectional views in FIGS. 1A and 1B are along the line A-A' in FIG. 1C.

As illustrated in FIG. 1A, the package structure 100 may include a package substrate 110, a package module 120 on the package substrate 110, an outer molding material layer 327 on the package substrate 110 around the package module 120, and a thermal interface material (TIM) layer 170 on the package module 120. The package structure 100 may also include a package lid 130 on the TIM layer 170 and attached to the outer molding material layer 327. The package lid 130 (e.g., dual package lid, dual lid or dual lid structure) may include a bottom lid portion 130B having a coefficient of thermal expansion (CTE) (e.g., first CTE), and a top lid portion 130A attached to the bottom lid portion 130B and having a CTE (e.g., second CTE) less than the CTE of the bottom lid portion 130B.

The package module 120 may include a first semiconductor die 141 and a plurality of second semiconductor dies 142 adjacent the first semiconductor die 141. The first semiconductor die 141 and second semiconductor dies 142 may be referred to collectively as the semiconductor dies 140. Although the package module 120 is illustrated as including a particular number of semiconductor dies having a particular arrangement, the number of semiconductor dies and the arrangement of the semiconductor dies is not limited to any particular number and arrangement. In particular, the package module 120 may include any number and arrangement of semiconductor dies.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include a plurality of metal layers (e.g., copper traces) and a plurality of metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include a plurality of metal layers (e.g., copper traces) and a plurality of metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate lower dielectric layer 116. The solder balls 110c may allow the package structure 100 to be securely mounted on a substrate such as a printed circuit board (PCB) and electrically coupled to the substrate. The solder balls 110c may contact the package substrate lower bonding pads 116a, respectively. The solder balls 110c may therefore be electrically connected to the package substrate upper bonding pads 114a by way of the package substrate lower bonding pads 116a, metal interconnect structures 116b, the through vias 112a and the metal interconnect structures 114b.

The package module 120 may be connected to the package substrate 110 by a plurality of C4 bumps 121 on the board-side surface of the package module 120. The C4 bumps 121 may be bonded to the package substrate upper bonding pads 114a in the package substrate 110. The C4 bumps 121 may be bonded to the package substrate upper bonding pads 114a by using, for example, solder reflow, compression bonding, thermo-compression bonding, etc. The C4 bumps 121 may include a metal pillar (e.g., copper pillar) and a solder bump (e.g., SnAg solder bump) on the metal pillar. In at least one embodiment, the solder bump may be collapsed to join the metal pillar of the C4 bump 121 to the package substrate upper bonding pads 114a.

A package underfill layer 119 may be formed on the package substrate 110 under and around the package module 120. The package underfill layer 119 may also be formed around the C4 bumps 121. The package underfill layer 119 may thereby securely fix the package module 120 to the package substrate 110. The package underfill layer 119 may be formed of an underfill material such as an epoxy-based polymeric material. Other suitable materials may be used for the package underfill layer 119.

An outer molding material layer 327 may be formed on the package substrate 110 around the package module 120. The outer molding material layer 327 may also be formed on and around the package underfill layer 119 that is under and around the package module 120. An upper surface of the outer molding material layer 327 may be substantially coplanar with an upper surface of the package module 120. The outer molding material layer 327 may include, for example, a polymeric material and in particular, an epoxy-based polymeric material (e.g., EMC). Other suitable material may be used in the outer molding material layer 327.

The TIM layer 170 may be located on the package module 120. The TIM layer 170 may include one or more layers. In at least one embodiment, a center of the TIM layer 170 may be substantially aligned with a center of the package module 120. The TIM layer 170 may have a low bulk thermal impedance and high thermal conductivity. The TIM layer 170 may cover an entire area of the upper surface of the package module 120. In at least one embodiment, the TIM layer 170 may have a thickness (e.g., a greatest thickness in the z-direction) in a range from 100µm to 300µm. The TIM layer 170 may be attached to the upper surface of the package module 120 by a thermally conductive adhesive (not shown).

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60°C. Other materials in the TIM layer 170 are within the contemplated scope of this disclosure.

The TIM layer 170 may be formed on the package module 120 to dissipate of heat generated during operation of the package structure 100 (e.g., operation of the semiconductor dies 140). The TIM layer 170 may have a low bulk thermal impedance and high thermal conductivity. The bond-line-thickness (BLT) (e.g., a distance between the package lid 130 and the package module 120) may be less than about 100µm, although greater or lesser distances may be used. The BLT may also be substantially uniform over the entire area of the upper surface of the package module 120.

An adhesive layer 160 may be formed on the upper surface of the outer molding material layer 327. The adhesive layer 160 may serve to contain a spread of the TIM layer 170 as the TIM layer 170 is compressed between the package lid 130 and the package module 120. A thickness of the adhesive layer 160 may be in a range from 50 µm to 200 µm. In at least one embodiment, the thickness of the adhesive layer 160 may be substantially the same as a thickness of the TIM layer 170. The adhesive layer 160 may include, for example, a silicone adhesive (e.g., containing aluminum oxide, zinc oxide, resin, etc.) or an epoxy adhesive. Other suitable adhesives may be used.

The package lid 130 may be located on the TIM layer 170 and attached to the outer molding material layer 327. The package lid 130 may be attached to the outer molding material layer 327 by the adhesive layer 160. The package lid 130 may cover an entirety of the package module 120 and an entirety of the outer molding material layer 327. The package lid 130 may contact (e.g., directly contact) at least a portion of the TIM layer 170. In one or more embodiments, the package lid 130 may directly contact an entire upper surface of the TIM layer 170. The TIM layer 170 and the adhesive layer 160 may be compressed between the package lid 130 and the package module 120.

The bottom lid portion 130B may be attached to the upper surface of the outer molding material layer 327 with the adhesive layer 160. An outer sidewall of the package lid 130 may be substantially aligned with an outer sidewall of the outer molding material layer 327. The package lid 130 may also include a bonding layer 135 on the bottom lid portion 130B. The bonding layer 135 may be configured to bond the top lid portion 130A to the bottom lid portion 130B. The bonding layer 135 may include an adhesive material such as a silicone adhesive (e.g., containing aluminum oxide, zinc oxide, resin, etc.) or an epoxy adhesive. Other suitable bonding materials may be used in the bonding layer 135.

The first CTE of the bottom lid portion may be in a range from 17 to 25. The bottom lid portion 130B may include, for example, at least one of Cu, Ag, Al, stainless steel, CuAg alloy and CuNi alloy. The second CTE of the top lid portion 130A may be in a range from 1 to 10. The top lid portion 130A may include, for example, at least one of Kovar, Invar, Co, Cu/Mo alloy, SiAl, AlN, AlSiN, AlSiC, CuSiC AgD (silver-diamond composite), CuD (copper-diamond composite), diamond substrate (e.g., diamond plate), and Alloy42.

A thickness of the bottom lid portion 130B may be substantially uniform over an entirety of the bottom lid portion 130B. A thickness of the top lid portion 130A may be substantially uniform over an entirety of the top lid portion 130A. In at least one embodiment, at least one of a thickness of the bottom lid portion 130B and a thickness of the top lid portion 130A may be used to control a morphology of the package lid 130 to match a CoW die warp profile. In at least one embodiment, a thickness of the top lid portion 130A may be substantially the same as the thickness of the bottom lid portion 130B in order to control a morphology of the package lid 130 to match a CoW die warp profile. In at least one embodiment, the thickness of the top lid portion 130A may be in a range from 0.5 mm to 1.5 mm, and the thickness of the bottom lid portion 130B may be in a range from 0.5 mm to 1.5 mm. In at least one embodiment, the thickness of the top lid portion 130A may be about 1.0 mm and the thickness of the bottom lid portion 130B may be about 1.0 mm.

The package lid 130 may help to eliminate issues including package underfill delamination and TIM (e.g., metal TIM) bleeding. The package lid 130 may help to generate a matching die warp effect in the package structure 100. The package lid 130 may include a low CTE cavity on top of the package lid 130. In at least one embodiment, a heat sink may be attached to the package lid 130 of the package structure 100. The package lid 130 may also include a flattened package lid top surface that may effectively contact a system heat sink. The package lid 130 may help manage thermal and mechanical stress in a package structure 100 in a room temperature condition, high temperature condition and low temperature condition. Such conditions may occur, for example, during fabrication and/or testing of the package structure 100. The package lid 130 may improve overall package coefficient of performance (COP) (e.g., improve surface mount technology (SMT) yield). The package lid 130 may improve a thermal performance (e.g., low TIM1 & TIM2 BLT variation) of the package structure 100. The package lid 130 may help to inhibit die crack during a heat sink (HS) mount. The package lid 130 may also help to reduce TIM layer (e.g., TIM2) pumping out by providing a more flattened lid /heat sink contact surface). Thus, in short, the package lid 130 may help to reduce TIM1 bleeding after MR, reduce LSI crack stress, provide a better thermal performance (less TIM2 pump out), and provide a better SMT yield (less package warp).

Referring again to FIG. 1B, the package module 120 may include a lower RDL structure 120A and a lower molded portion 120B on the lower RDL structure 120A. The package module 120 may also include an upper RDL structure 120C on the lower molded portion 120B and an upper molded portion 120D on the upper RDL structure 120C.

In at least one embodiment, the lower RDL structure 120A may include a plurality of polymer layers 12 and a plurality of redistribution layers 12a stacked alternately. The number of the polymer layers 12 and/or the number of redistribution layers 12a in the lower RDL structure 120A are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof. Other suitable conductive materials may be within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on an upper surface of the polymer layers 12. The C4 bumps 121 may be formed on a board-side surface of the lower RDL structure 120A. The C4 bumps 121 may be electrically coupled to the redistribution layers 12a.

The lower molded portion 120B may be formed on the lower RDL structure 120A. The lower molded portion 120B may have a length in the x-direction that is substantially the same as a length in the x-direction of the lower RDL structure 120A. The lower molded portion 120B may have a width in the y-direction that is substantially the same as a width in the y-direction of the lower RDL structure 120A. The lower molded portion 120B may have a thickness in the z-direction greater than a thickness of the lower RDL structure 120A.

The lower molded portion 120B may include a lower molding material layer 127 (e.g., encapsulation layer) formed on the lower RDL structure 120A. In at least one embodiment, the lower molding material layer 127 may be formed of a curable material that may cure to form a hard, solid structure. The lower molding material layer 127 may include, for example, epoxy molding compound (EMC). In at least one embodiment, the lower molding material layer 127 may include a polymeric material and in particular, an epoxy-based polymeric material. Other suitable molding materials may be used.

In at least one embodiment, the lower molding material layer 127 may have a coefficient of thermal expansion (CTE) that is substantially similar to a CTE of the lower RDL structure 120A. In at least one embodiment, the lower molding material layer 127 may include an added material (e.g., filler material) for improving a property of the lower molding material layer 127 (e.g., thermal conductivity, CTE, etc.). The added material may include, for example, metal powder, metal oxide powder, etc. Other materials in the lower molding material layer 127 are within the contemplated scope of the disclosure.

The lower molded portion 120B of the package module 120 may also include one or more interconnect dies 10. The interconnect dies 10 may be surrounded (e.g., at least in the x-direction and y-direction) by the lower molding material layer 127. In at least one embodiment, the lower molding material layer 127 may contact a substantial entirety of the sidewalls of the interconnect dies 10 (e.g., the interconnect dies 10 may be substantially embedded in the lower molding material layer 127. The interconnect dies 10 may interconnect the semiconductor dies 140. The interconnect dies 10 may be passive interconnect dies or active interconnect dies 10.

The interconnect dies 10 may include one or more local silicon interconnect (LSI) dies 101 and one or more local redistribution interconnect (LRI) dies 201. In at least one embodiment, the interconnect dies 10 may include an LSI die 101 that interconnects (e.g., electrically couples) the first semiconductor die 141 to one or more second semiconductor dies 142. The LSI die 101 may include a bulk semiconductor portion 101a (e.g., bulk silicon portion) on the lower RDL structure 120A. The LSI die 101 may also include an interconnect portion 101b including metal interconnects 101b1 on the bulk semiconductor portion 101a. The LSI die 101 may also include one or more LSI bonding pads 104 on an upper surface of the LSI die 101. The LSI bonding pads 104 may be electrically coupled to the metal interconnects 101b1 in the interconnect portion 101b. The LSI die 101 may also include one or more through vias 106 (e.g., through silicon vias (TSVs)) in the bulk semiconductor portion 101a. The through vias 106 may electrically couple the metal interconnects 101b1 in the interconnect portion 101b to the redistribution layers 12a in the lower RDL structure 120A. Each of the metal interconnects 101b1, LSI bonding pads 104, and through vias 106 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

In at least one embodiment, the interconnect dies 10 may include an LRI die 201 that interconnects (e.g., electrically couples) the first semiconductor die 141 to one or more second semiconductor dies 142 on an opposite side of the first semiconductor die 141. The LRI die 201 may include a bulk semiconductor portion 201a (e.g., bulk silicon portion) on the lower RDL structure 120A. The LRI die 201 may also include a redistribution portion 201c including metal redistribution layers 201c1 on the bulk semiconductor portion 201a. The LRI die 201 may also include one or more LRI bonding pads 204 on an upper surface of the LRI die 201. The LRI bonding pads 204 may be electrically coupled to the metal redistribution layers 201c1 in the redistribution portion 201c. The LRI die 201 may also include one or more through vias 206 (e.g., TSVs) in the bulk semiconductor portion 201a. The through vias 106 may electrically couple the metal redistribution layers 201c1 in the redistribution portion 201c to the redistribution layers 12a in the lower RDL structure 120A. Each of the metal redistribution layers 201b1, LRI bonding pads 204, and through vias 206 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B of the package module 120 may also include one or more through insulator vias (TIVs) 123 in the lower molding material layer 127. The TIVs 123 may be located adjacent the interconnect dies 10 and may have a thickness substantially equal to a thickness of the lower molding material layer 127. The TIVs 123 may be connected to the redistribution layers 12a of the lower RDL structure 120A. The TIVs 123 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B may also integrate additional elements, such as a stand-alone IPDs (not shown). In at least one embodiment, the IPDs may be located in the lower molding material layer 127 underneath one or more of the first semiconductor die 141, second semiconductor die 142, third semiconductor die (not shown), fourth semiconductor die (not shown), fifth semiconductor die (not shown)and sixth semiconductor die (not shown)to support signal communication.

The lower molded portion 120B may also integrate additional elements, such as a stand-alone integrated passive devices (IPDs) (not shown). In at least one embodiment, the IPDs may be located in the lower molding material layer 127 underneath one or more of the first semiconductor die 141 or second semiconductor dies 142.

Referring again to FIG. 1B, the upper RDL structure 120C of the package module 120 may have a structure substantially similar to that of the lower RDL structure 120A. In particular, the upper RDL structure 120C may include a plurality of polymer layers 13 and a plurality of redistribution layers 13a stacked alternately. The number of the polymer layers 13 and/or the number of redistribution layers 13a in the upper RDL structure 120C are not limited by the disclosure. The materials that may be used in the polymer layers 13 may be substantially the same as the materials that may be used in the polymer layers 12. The materials that may be used in the redistribution layers 13a may bs substantially the same as the materials that may be used in the redistribution layers 12a. The structure (e.g., thickness) of the redistribution layers 13a may be substantially the same as the structure of the redistribution layers 12a.

The redistribution layers 13a in the upper RDL structure 120C may contact the TIVs 123 in the lower molded portion 120B. The redistribution layers 13a may be electrically coupled to the redistribution layers 12a in the lower RDL structure 120A by the TIVs 123. The redistribution layers 13a may also contact the LSI bonding pads 104 in the LSI die 101 and the LRI bonding pads in the LRI die 201.

The upper RDL structure 120C may also include a plurality of bonding pads 214 on an upper surface of the upper RDL structure 120C. The bonding pads 214 may be substantially similar to the LSI bonding pads 104 and LRI bonding pads 204. In particular, the materials that may be used in the bonding pads 214 may be substantially the same as the materials that may be used in the LSI bonding pads 104 and LRI bonding pads 204.

As illustrated in FIG. 1B, upper molded portion 120D of the package module 120 may be formed on the upper RDL structure 120C. The upper molded portion 120D may include the semiconductor dies 140. The semiconductor dies 140 may be connected to the bonding pads 214 on the upper surface of the upper RDL structure 120C by a plurality of die connection structures such as microbumps 219. The microbumps 219 may each include a copper post and a solder bump on the copper post. The microbumps 219 may be bonded by the solder bump to bonding pads 214. The microbumps 219 may be electrically coupled to the TIVs 123, LSI die 101 and LRI die 201 by the upper RDL structure 120C.

The package module 120 may also include a package module underfill layer 129 that is formed (e.g., individually or collectively) under and around each of the semiconductor dies 140. The package module underfill layer 129 may also be formed around the microbumps 219. The package module underfill layer 129 may thereby fix each of the semiconductor dies 140 to the upper RDL structure 120C. The package module underfill layer 129 may be formed of an epoxy-based polymeric material.

Each of the semiconductor dies 140 may include, for example, a singular semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor die 142 may include an ancillary die (e.g, memory/SOC die, HBM die, etc.).

The package module 120 may also include an upper molding material layer 227 formed around the semiconductor dies 140. The upper molding material layer 227 may also be formed on and around the package module underfill layer 129. The upper molding material layer 227 may have an outer sidewall that is substantially aligned with an outer sidewall of the polymer layers 13 in the upper RDL structure 120C, an outer sidewall of the lower molding material layer 127 and an outer sidewall of the polymer layers 12 in the lower RDL structure 120A.

In at least one embodiment, the upper molding material layer 227 may be formed on sidewalls (inner sidewall and outer sidewall) of each of the semiconductor dies 140. In at least one embodiment, an upper surface of the package module underfill layer 129 may be recessed from upper surface of the semiconductor dies 140a. In that case, the upper molding material layer 227 may be formed on the upper surface of the package module underfill layer 129 between the semiconductor dies 140. The upper molding material layer 227 may be formed between and bonded to the sidewalls of each of the semiconductor dies 140. The upper molding material layer 227 may also be bonded to the chip-side surface of the upper RDL structure 120C and the package module underfill layer 129.

As illustrated in FIG. 1B, the upper molding material layer 227 may include an upper surface that is substantially coplanar with the upper surface 140a of the semiconductor dies 140. The upper surface of the upper molding material layer 227 may alternatively or additionally include a recessed upper surface (not shown) that is recessed in the z-direction from the upper surface 140a of the semiconductor dies 140. In at least one embodiment, the recessed upper surface may constitute an entirety of an upper surface of the upper molding material layer 227.

In at least one embodiment, the upper molding material layer 227 may be formed of a curable material that may cure to form a hard, solid structure. The upper molding material layer 227 may include, for example, epoxy molding compound (EMC). In at least one embodiment, the upper molding material layer 227 may include a material that is substantially similar to the package module underfill layer 129, and or substantially similar to the lower molding material layer 127 in the lower molded portion 120B. In at least one embodiment, the upper molding material layer 227 may include a polymeric material and in particular, an epoxy-based polymeric material. Other suitable molding materials may be within the contemplated scope of disclosure.

In at least one embodiment, the upper molding material layer 227 may have a CTE that is substantially similar to a CTE of the upper RDL structure 120C, a CTE of the lower molded portion 120B and/or a CTE of the lower RDL structure 120A. In at least one embodiment, the upper molding material layer 227 may include an added material (e.g., filler material) for improving a property of the upper molding material layer 227 (e.g., thermal conductivity, CTE, etc.). The added material may include, for example, metal powder, metal oxide powder, etc. Other materials in the upper molding material layer 227 are within the contemplated scope of the disclosure.

Referring again to FIG. 1C, the package lid 130, TIM layer 170 and adhesive layer 160 are omitted from FIG. 1C for ease of explanation. A location of the LSI die 101 and LRI die 201 beneath the semiconductor dies 140 are shown as shadows in FIG. 1C.

As illustrated in FIG. 1C, the second semiconductor dies 142 may be substantially aligned in columns extending in the y-direction on opposing sides of the first semiconductor die 141. The second semiconductor dies 142 may also be substantially aligned in rows extending in the x-direction on the opposing sides of the first semiconductor die 141. The upper molding material layer 227 in the package module 120 may be formed around all of the semiconductor dies 140.

As further illustrated in FIG. 1C, the LSI die 101 may extend lengthwise in the y-direction. The LSI die 101 may be located under the first semiconductor die 141 and one or more of the second semiconductor dies 142 on a side of the first semiconductor die 141. The LRI die 201 may be located under the first semiconductor die 141 and one or more of the second semiconductor dies 142 on an opposite side of the first semiconductor die 141.

As further illustrated in FIG. 1C, the package structure 100 may have a substantially rectangular shape extending lengthwise in the y-direction. The first semiconductor die 141 may also have a substantially rectangular shape extending lengthwise in the y-direction. Other suitable shapes are within the contemplated scope of disclosure. The outer molding material layer 327 may have a substantially frame shape. The adhesive layer 160 (not shown) may cover an entirety of the outer molding material layer 327. In at least one embodiment, an outer sidewall of the adhesive layer 160 may be coextensive with the outer sidewall of the outer molding material layer 327, and an inner sidewall of the adhesive layer 160 may be coextensive with an inner sidewall of the outer molding material layer 327.

An outer shape of the package module 120 may be substantially defined by an outer shape of the upper molding material layer 227. The upper molding material layer 227 may have a width W1 in a range from 10 mm to 80 mm. The outer molding material layer 327 may have a width W2 less than the width W1 of the upper molding material layer 227. The width W1 may be substantially uniform around an entirety of the upper molding material layer 227. In at least one embodiment, the width W2 of the outer molding material layer 327 may be in a range from 10% to 30% of the width W1 of the upper molding material layer 227.

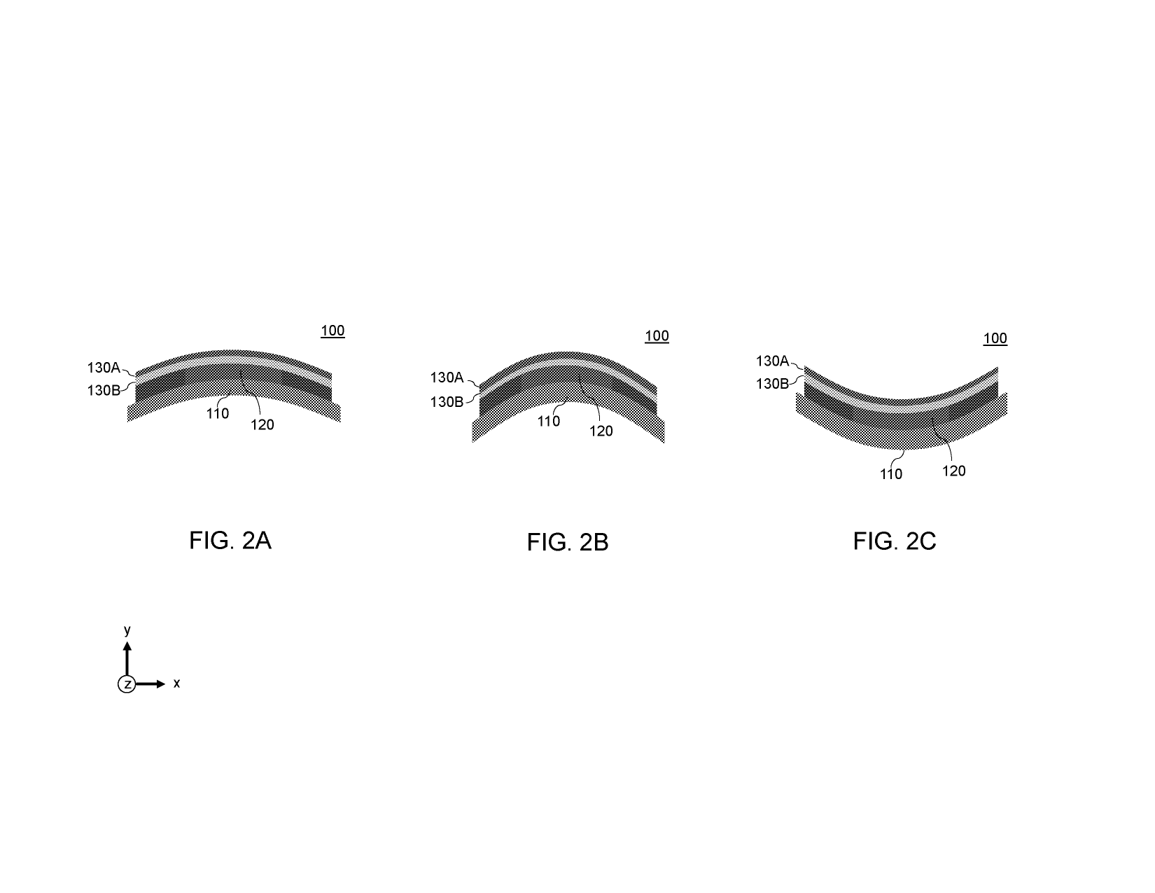

FIGS. 2A-2C are schematic illustrations of the package structure 100 under various temperature conditions according to one or more embodiments. FIG. 2A is a schematic illustration of the package structure 100 under a room temperature condition according to one or more embodiments. As illustrated in FIG. 2A, a warp profile of the package lid 130 under a room temperature condition may be substantially matched with the warp profile of the package module 120 and the package substrate 110.

FIG. 2B is a schematic illustration of the package structure 100 under a high temperature condition according to one or more embodiments. As illustrated in FIG. 2B, a warp profile of the package lid 130 under a high temperature condition may be substantially matched with the warp profile of the package module 120 and the package substrate 110.

FIG. 2C is a schematic illustration of the package structure 100 under a low temperature condition according to one or more embodiments. As illustrated in FIG. 2B, a warp profile of the package lid 130 under a low temperature condition may be substantially matched with the warp profile of the package module 120 and the package substrate 110.

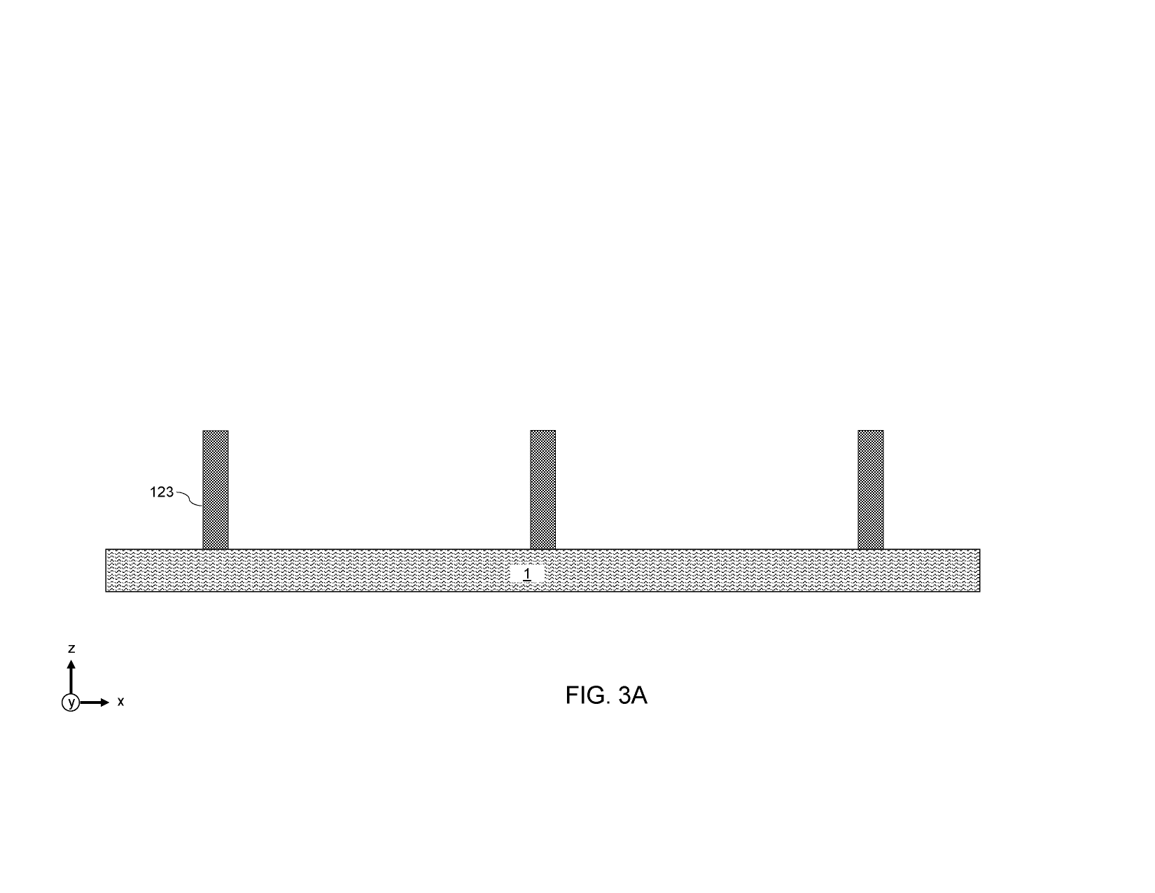

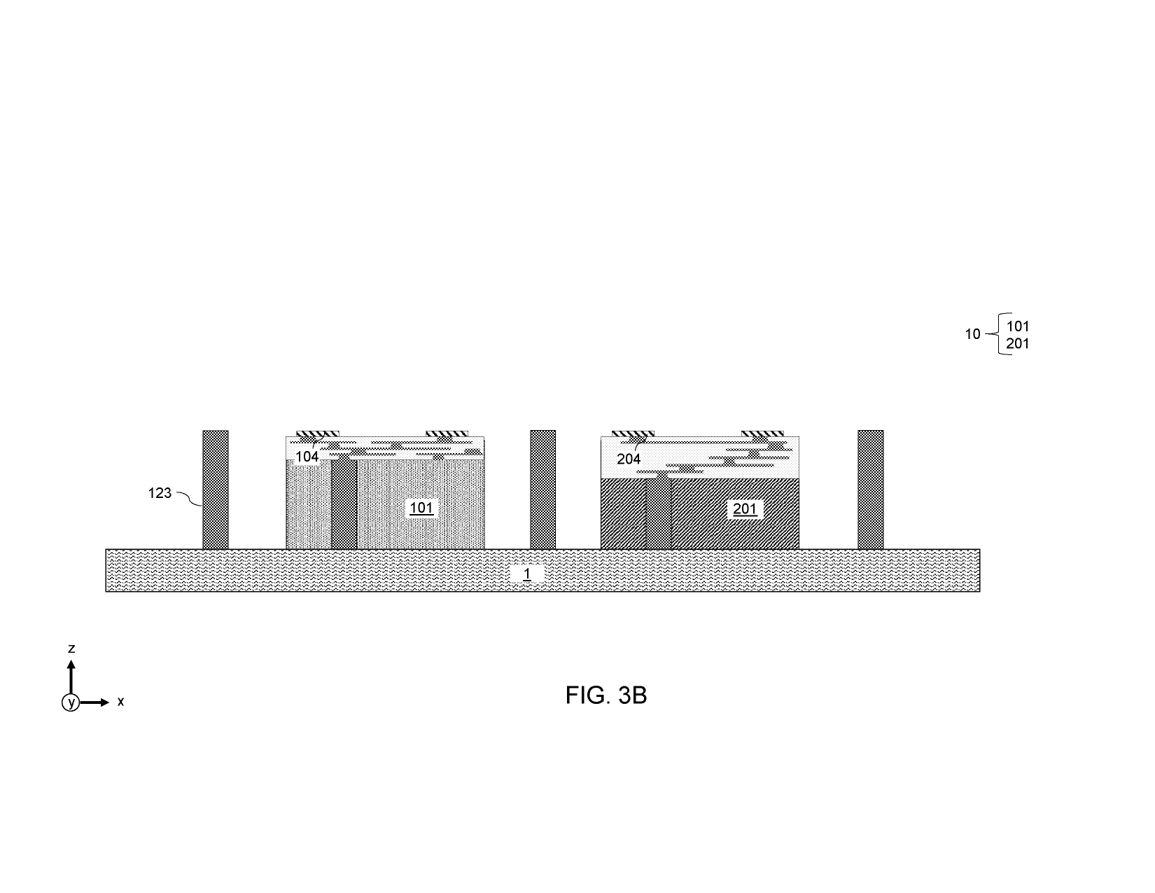

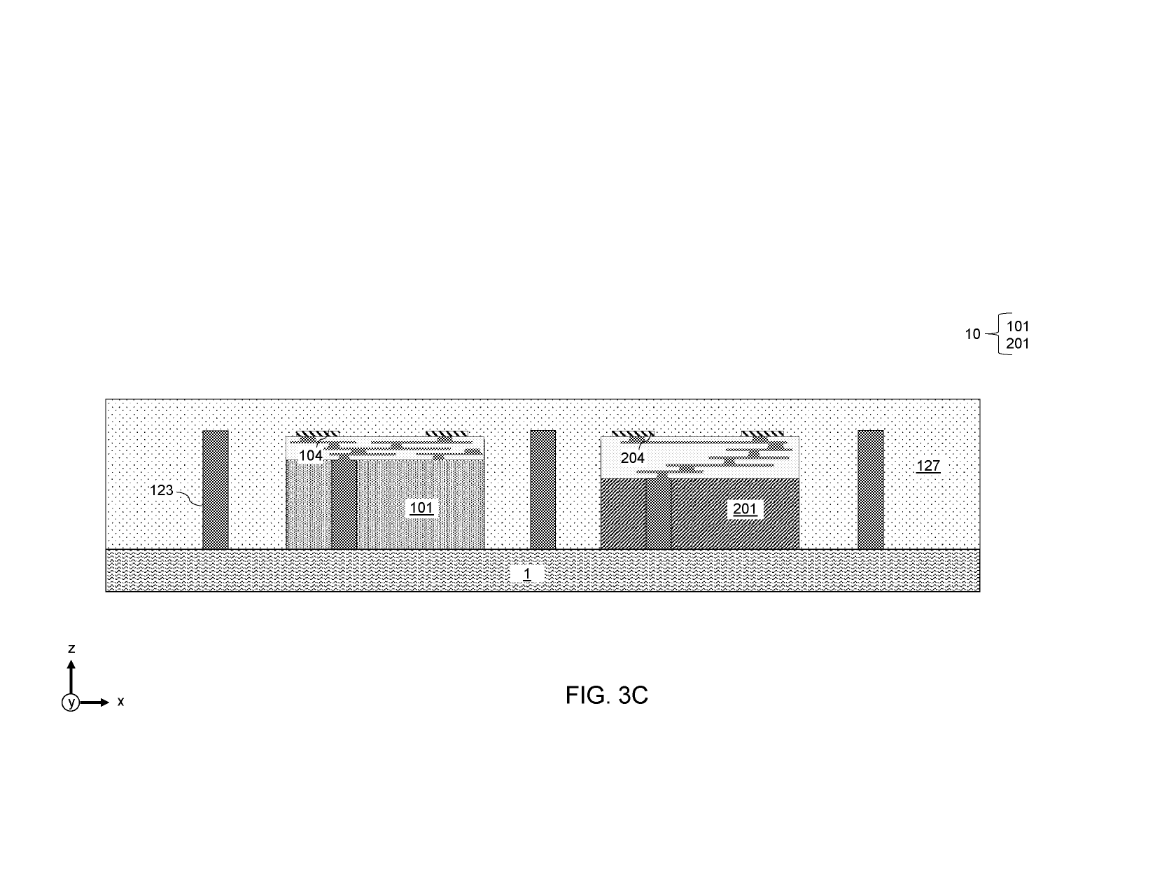

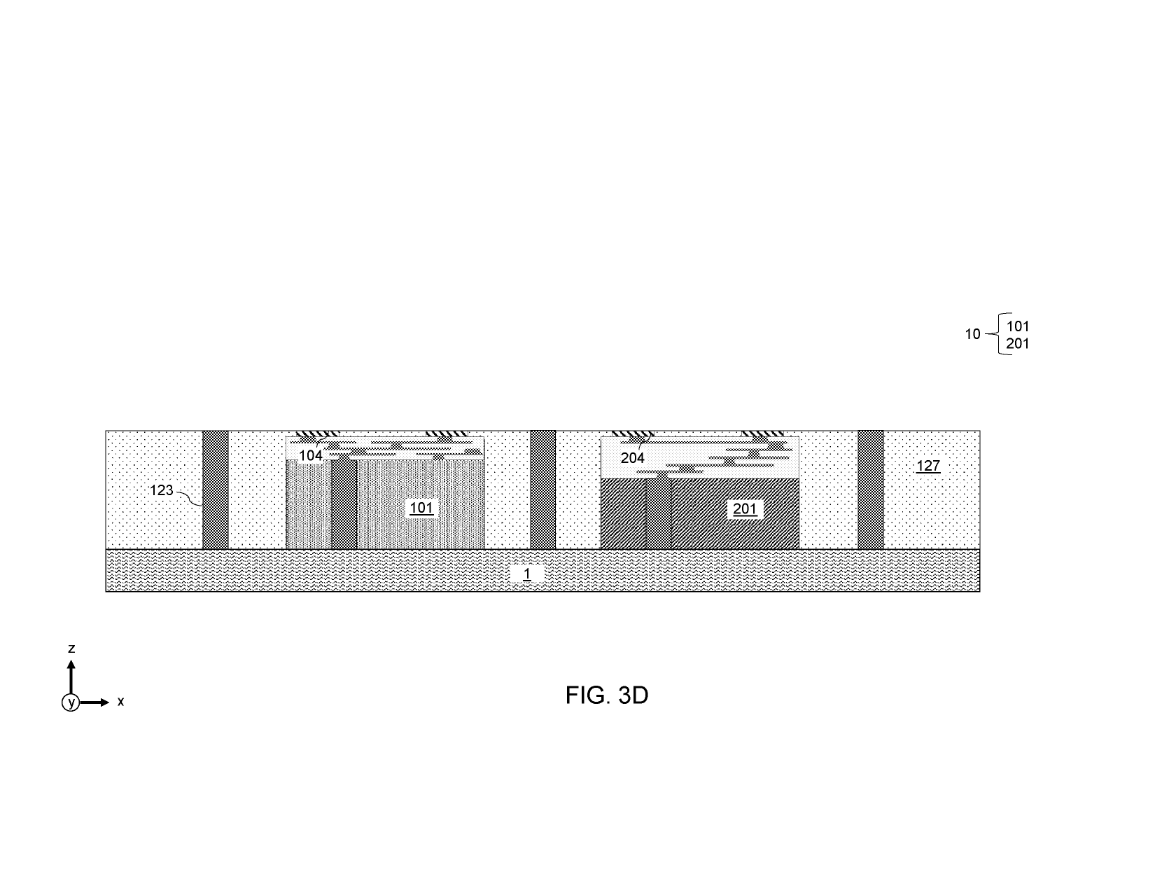

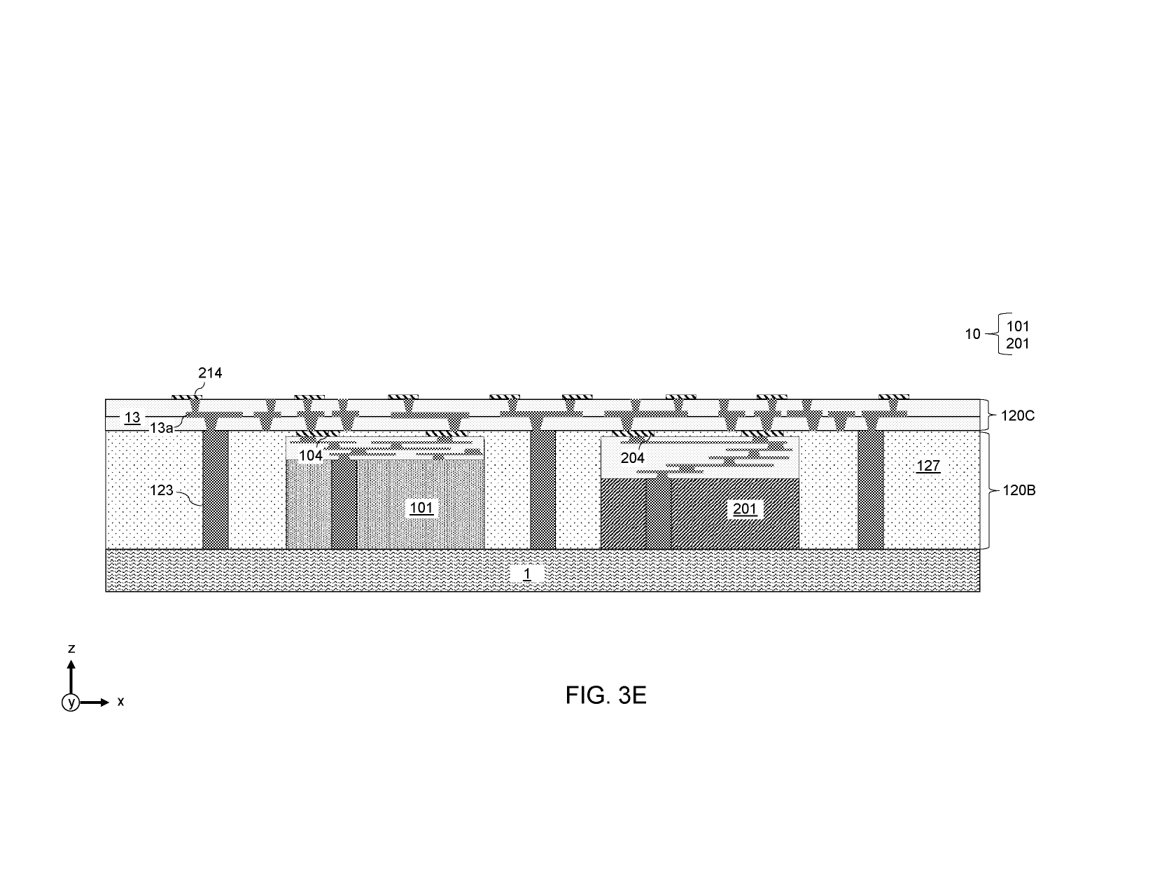

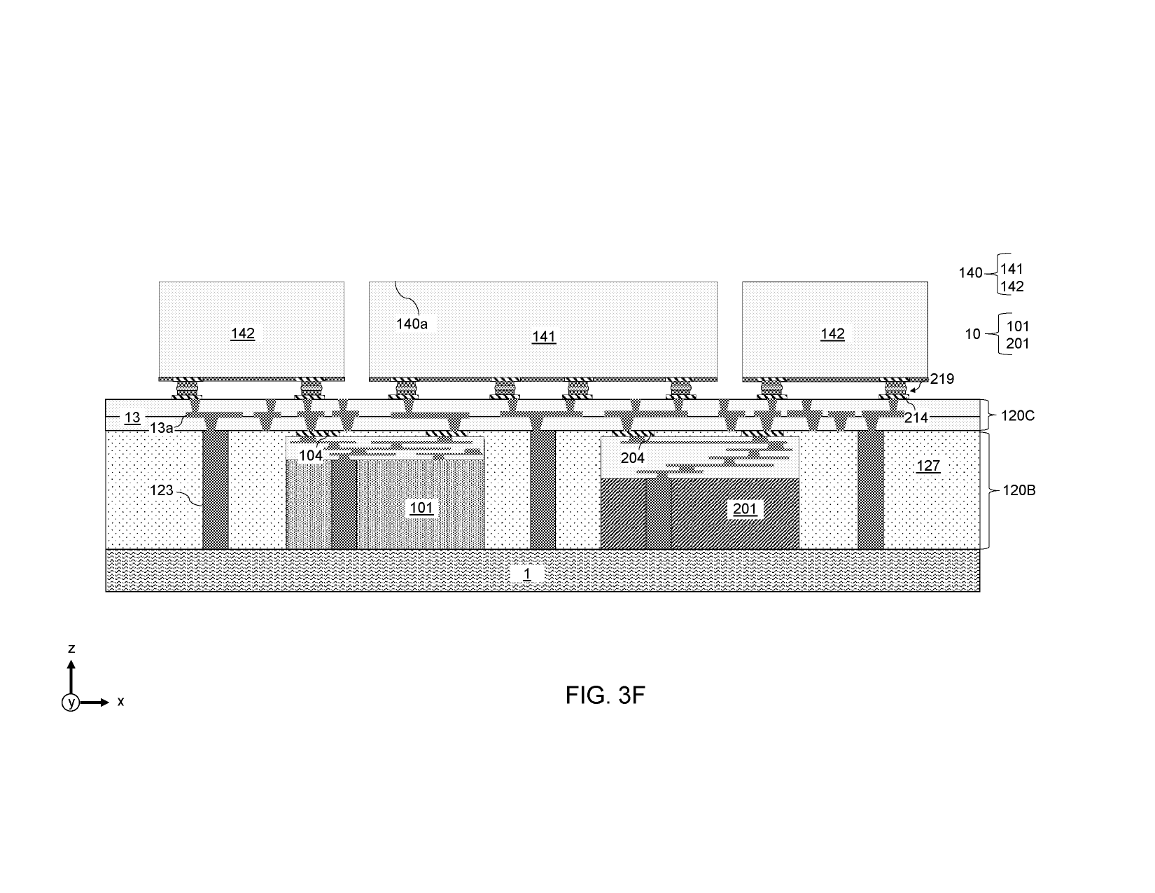

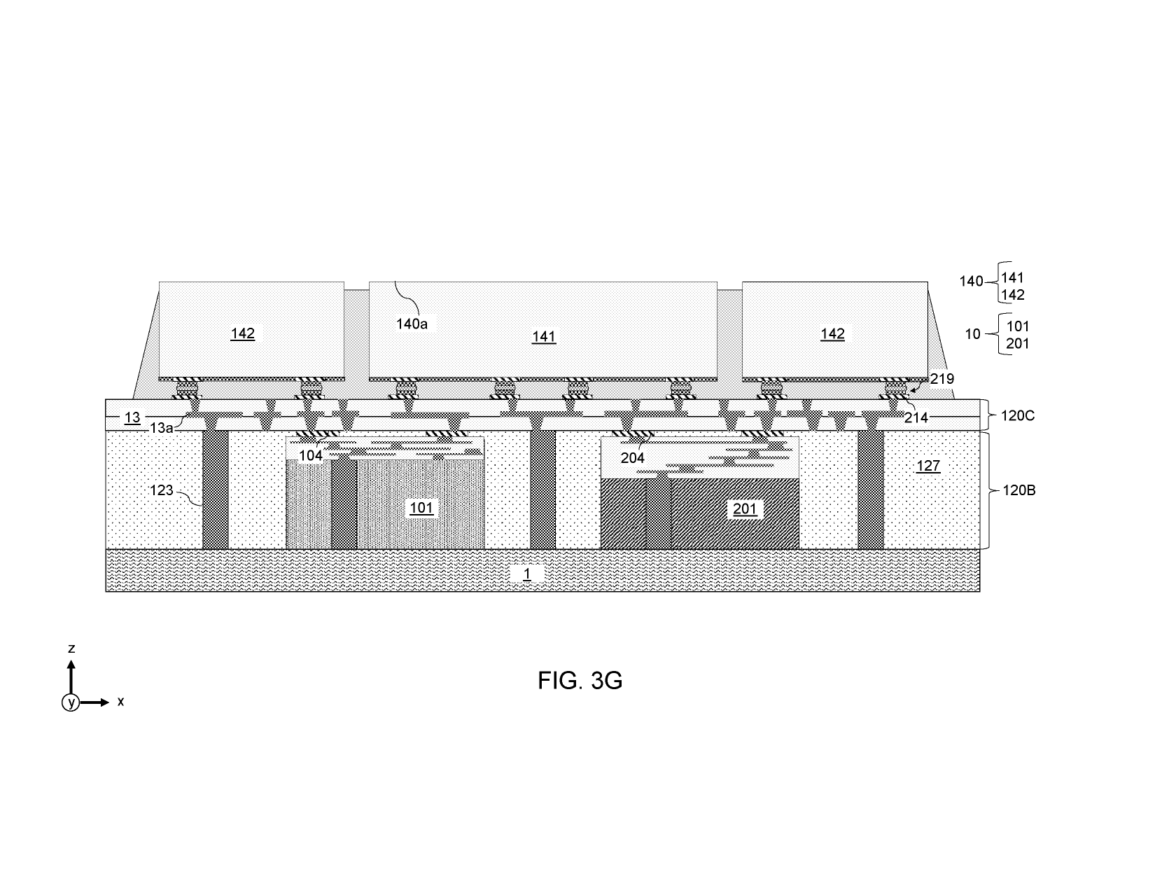

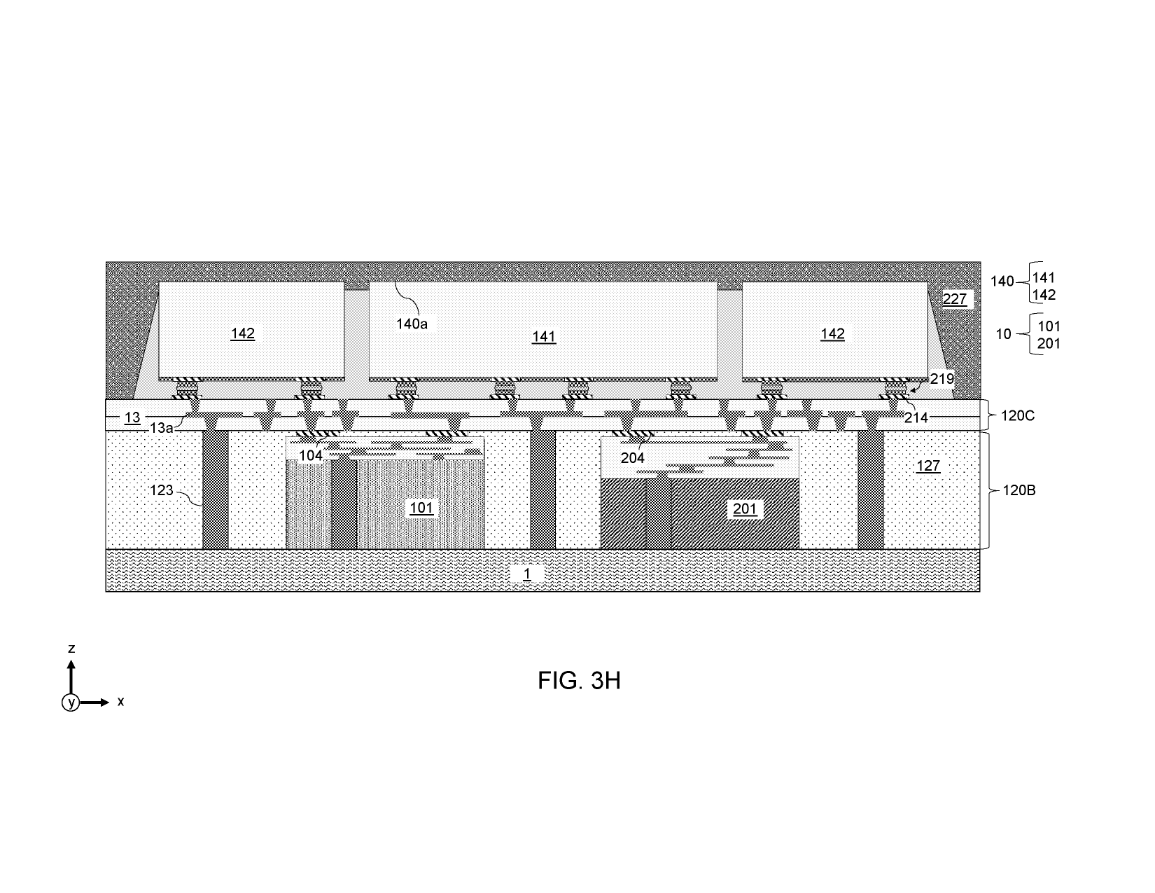

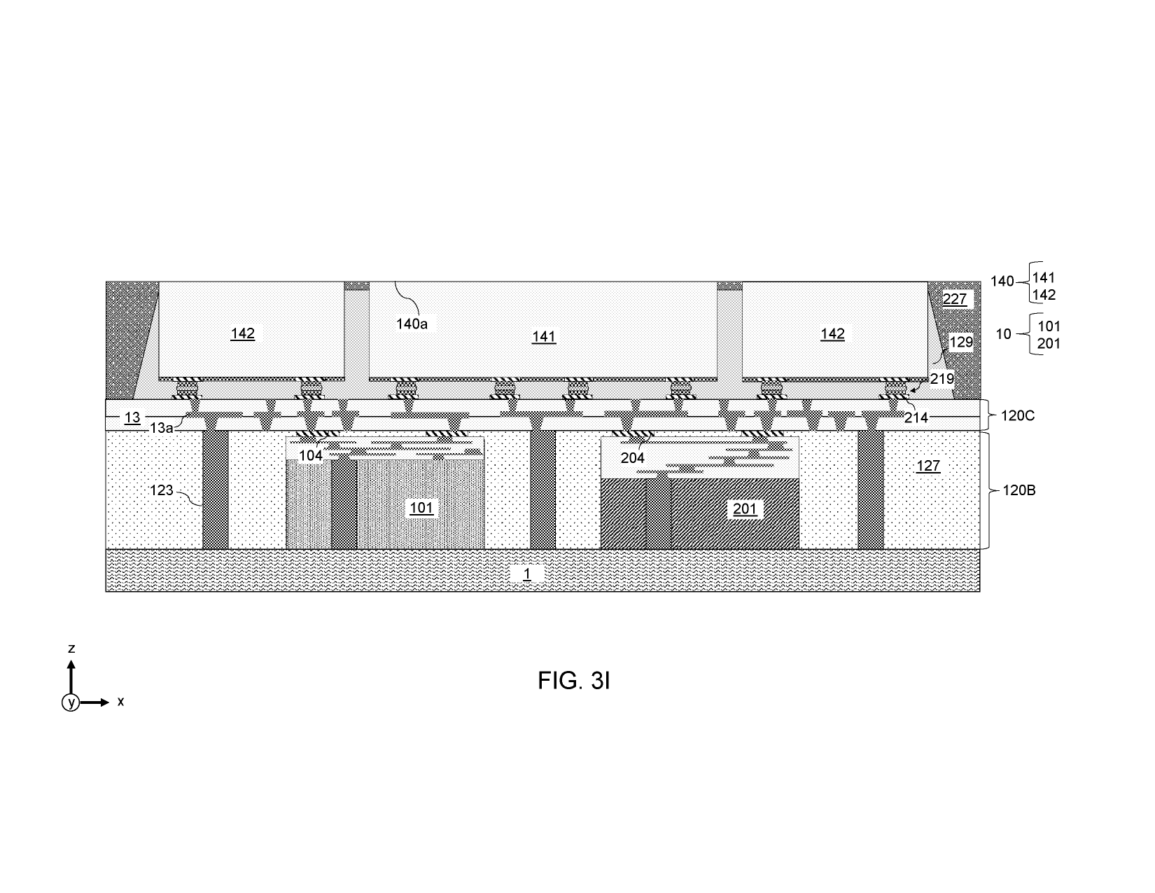

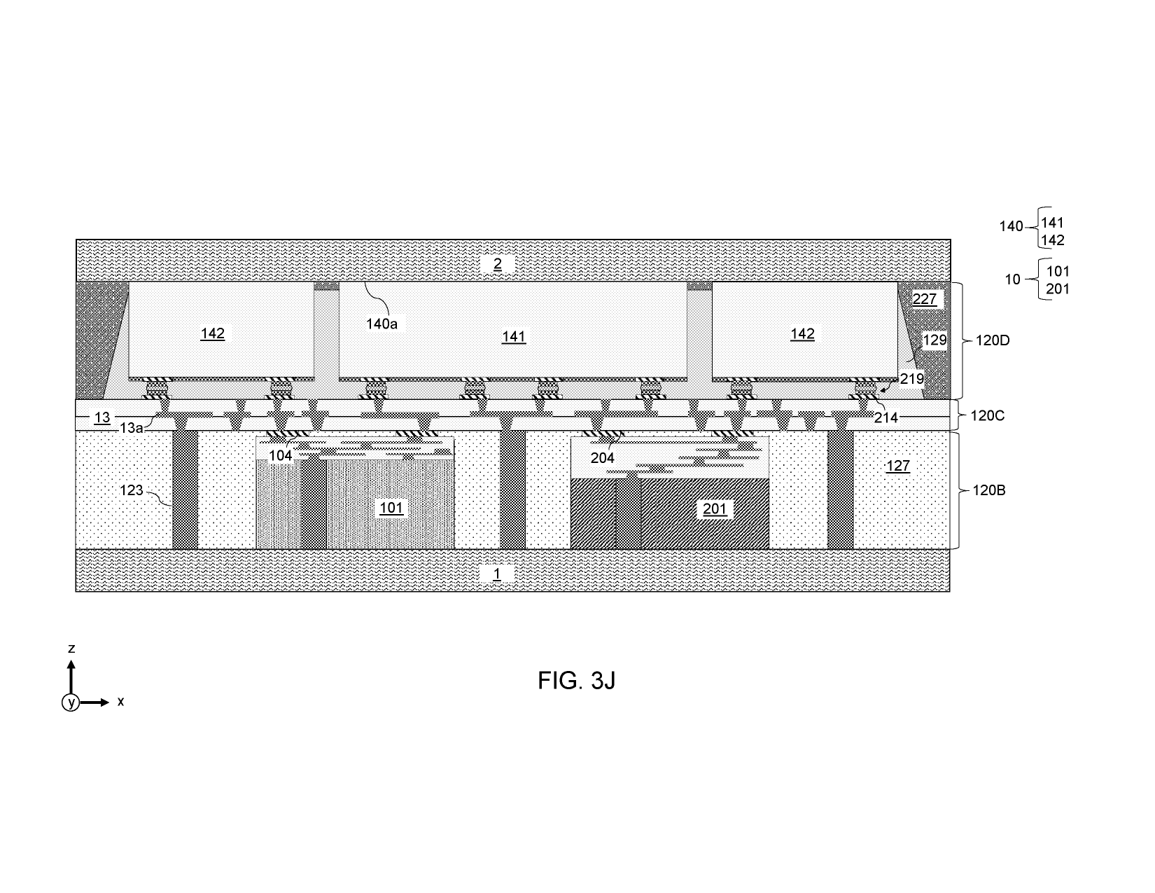

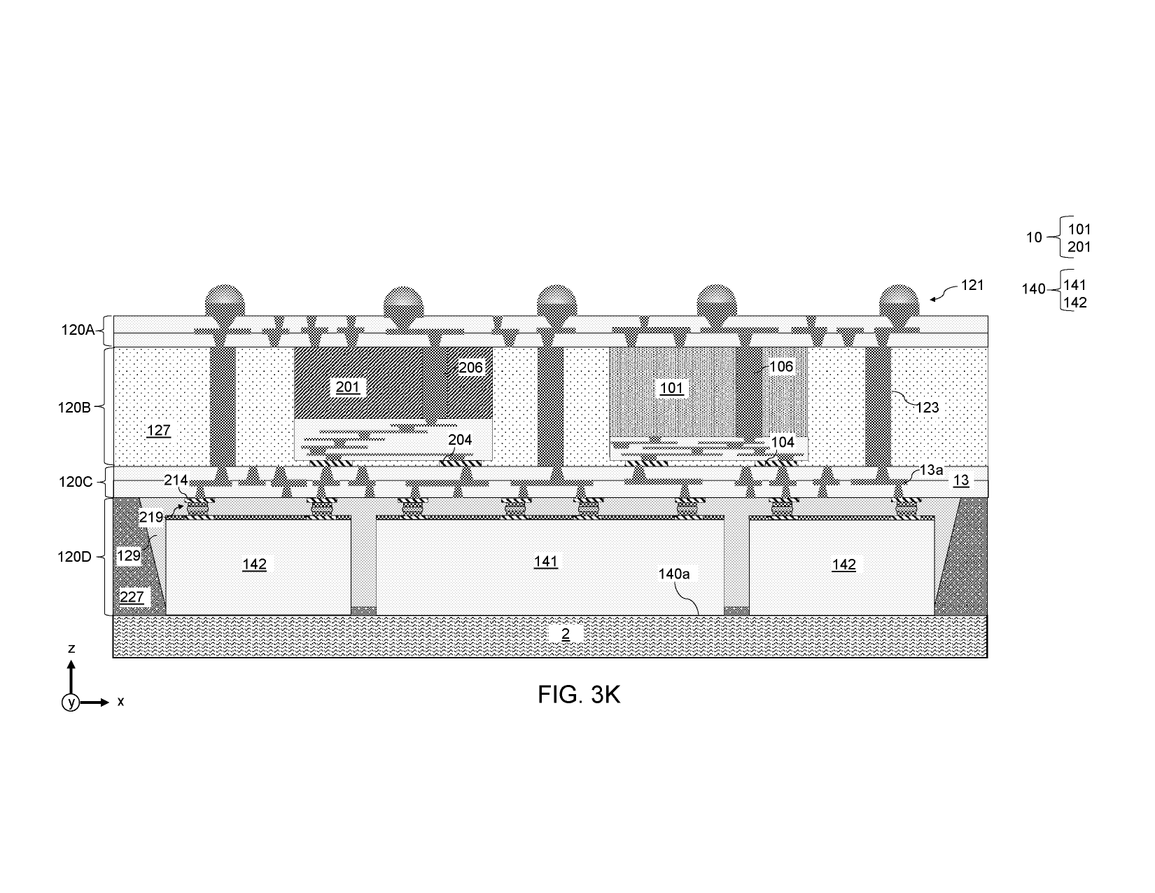

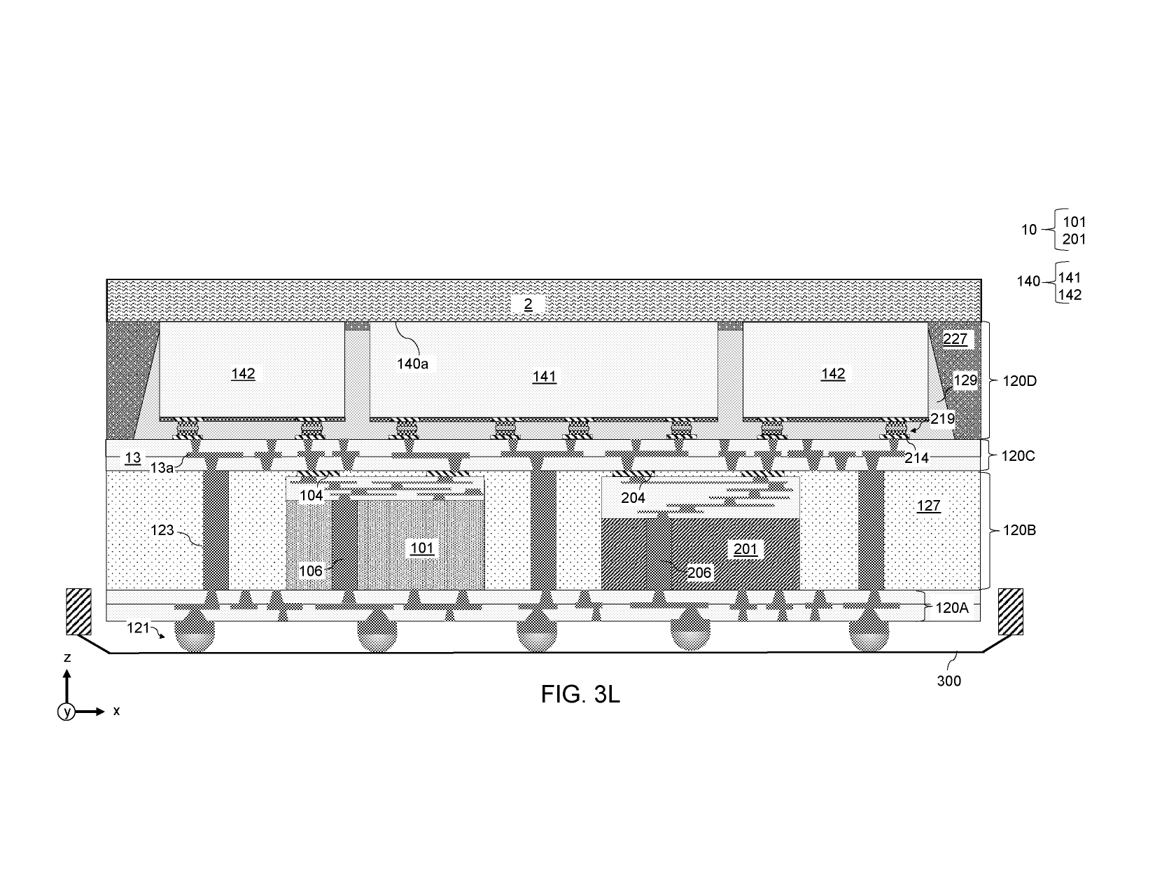

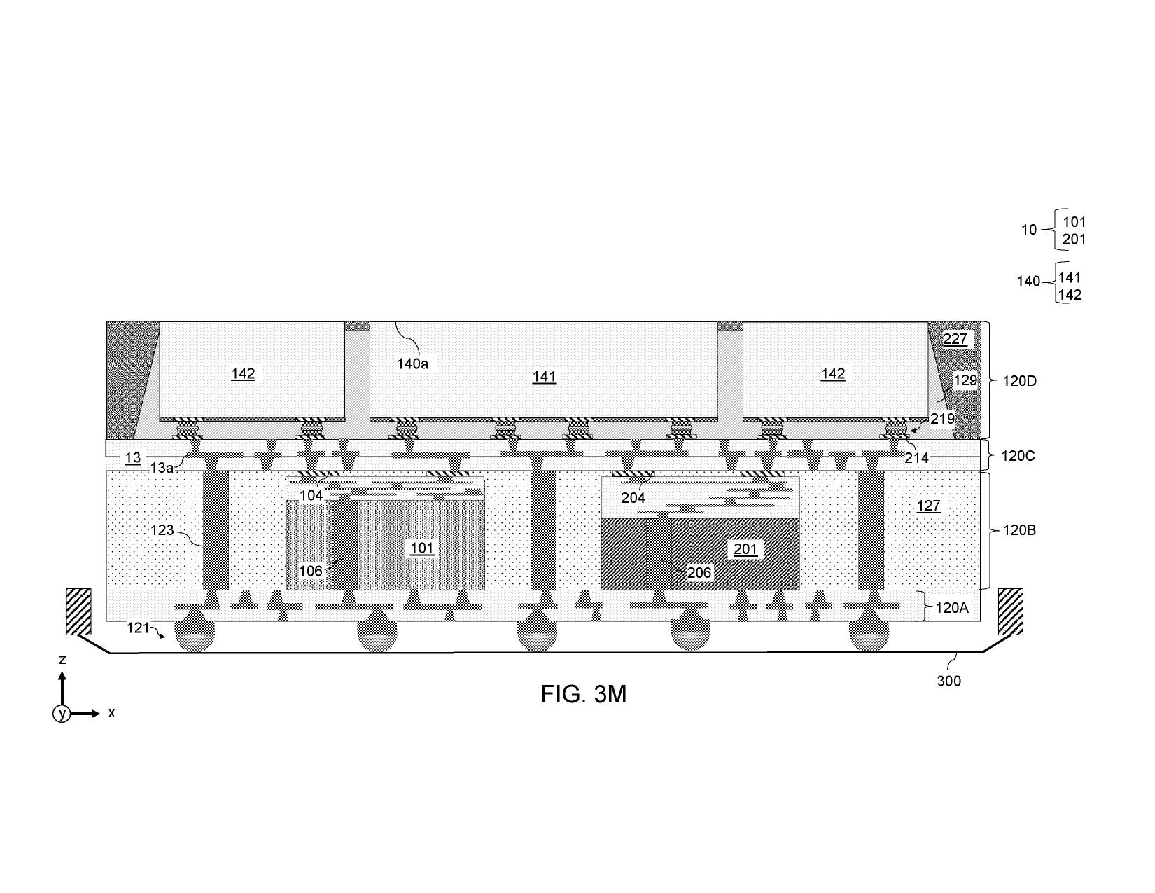

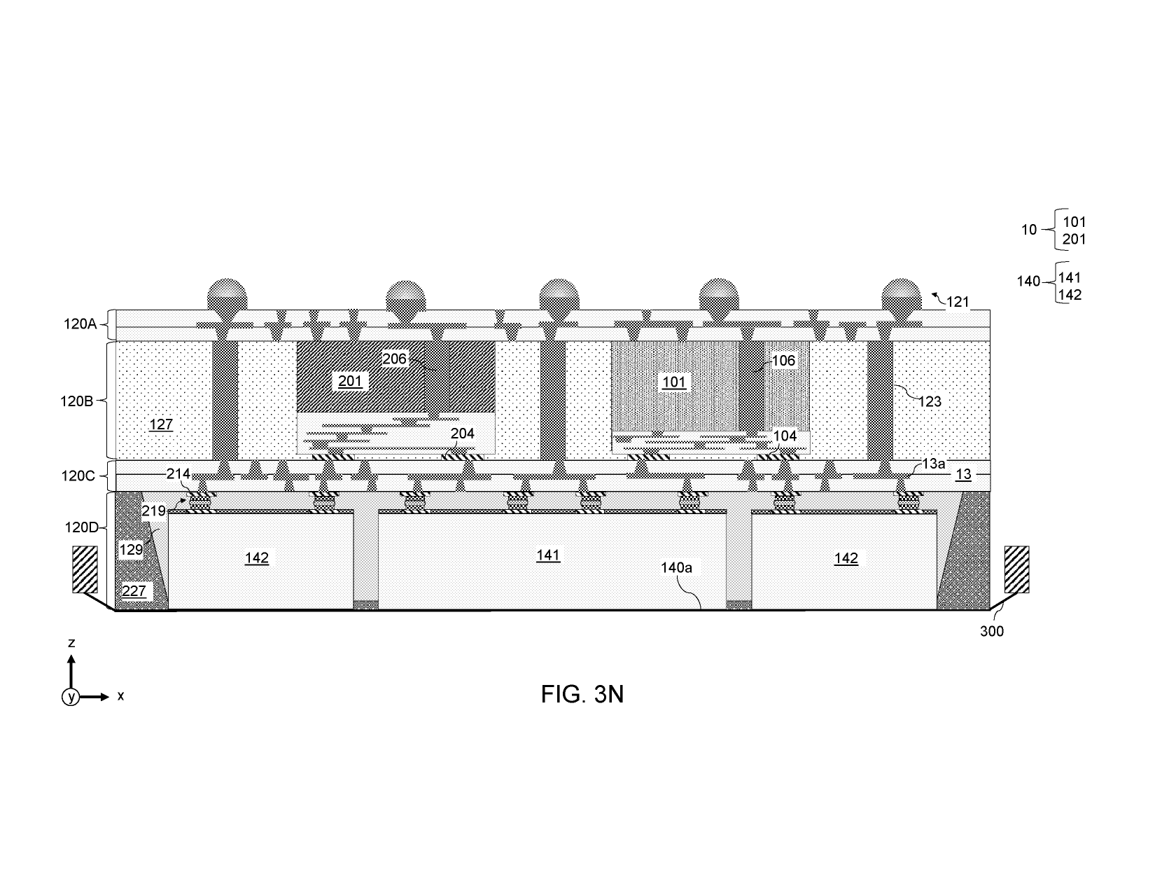

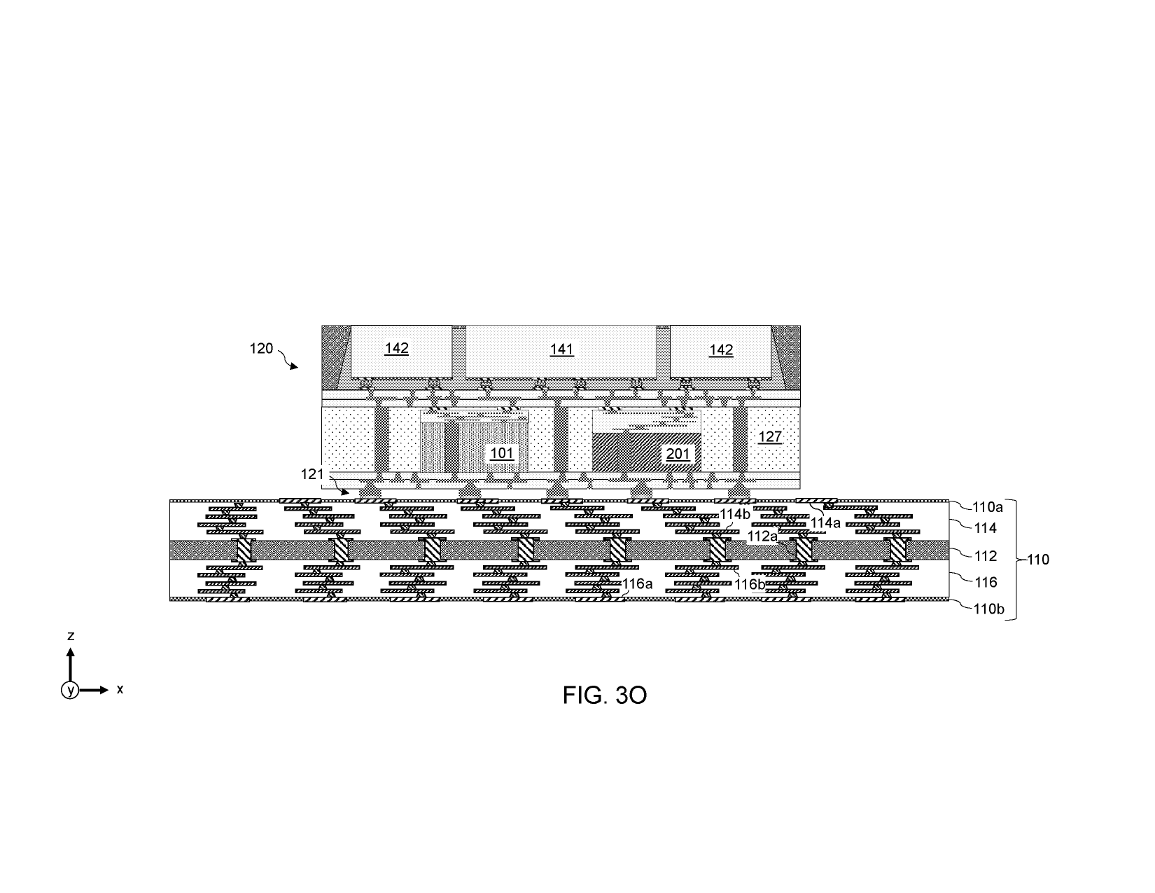

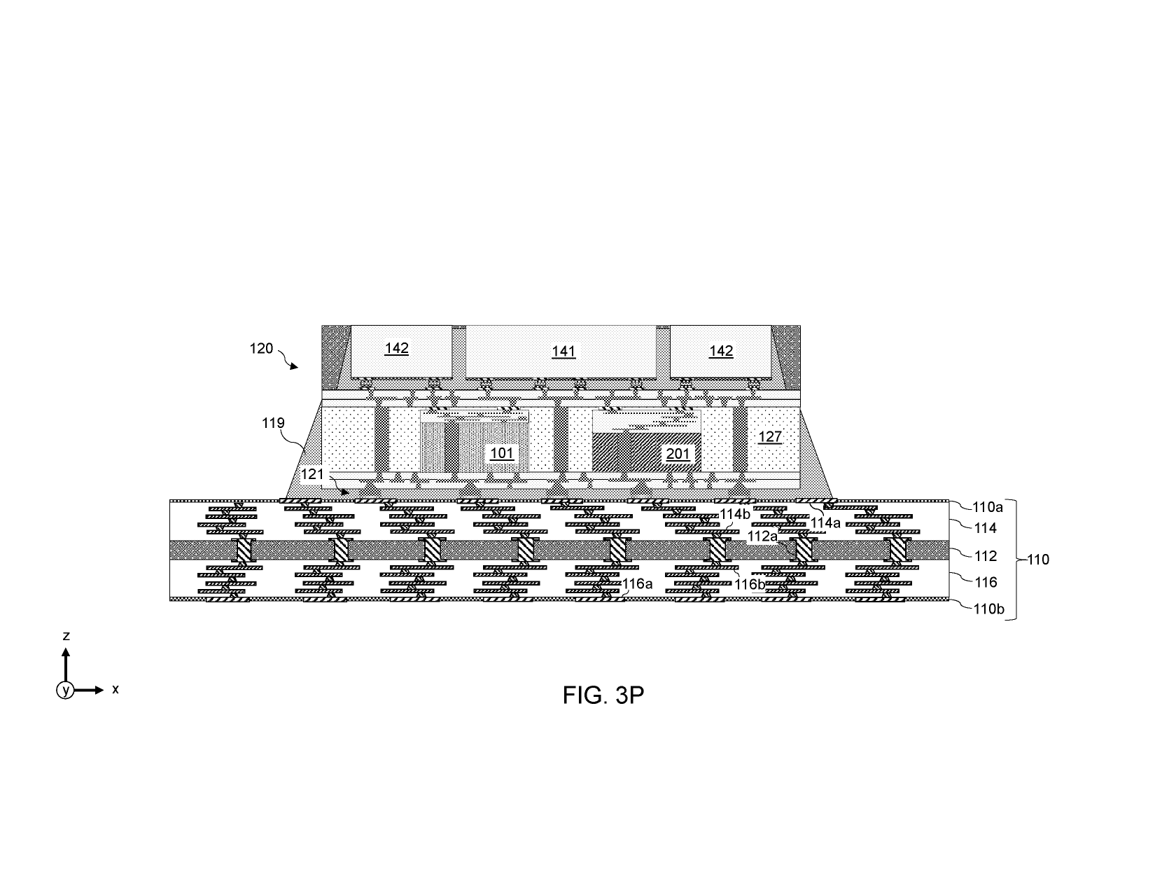

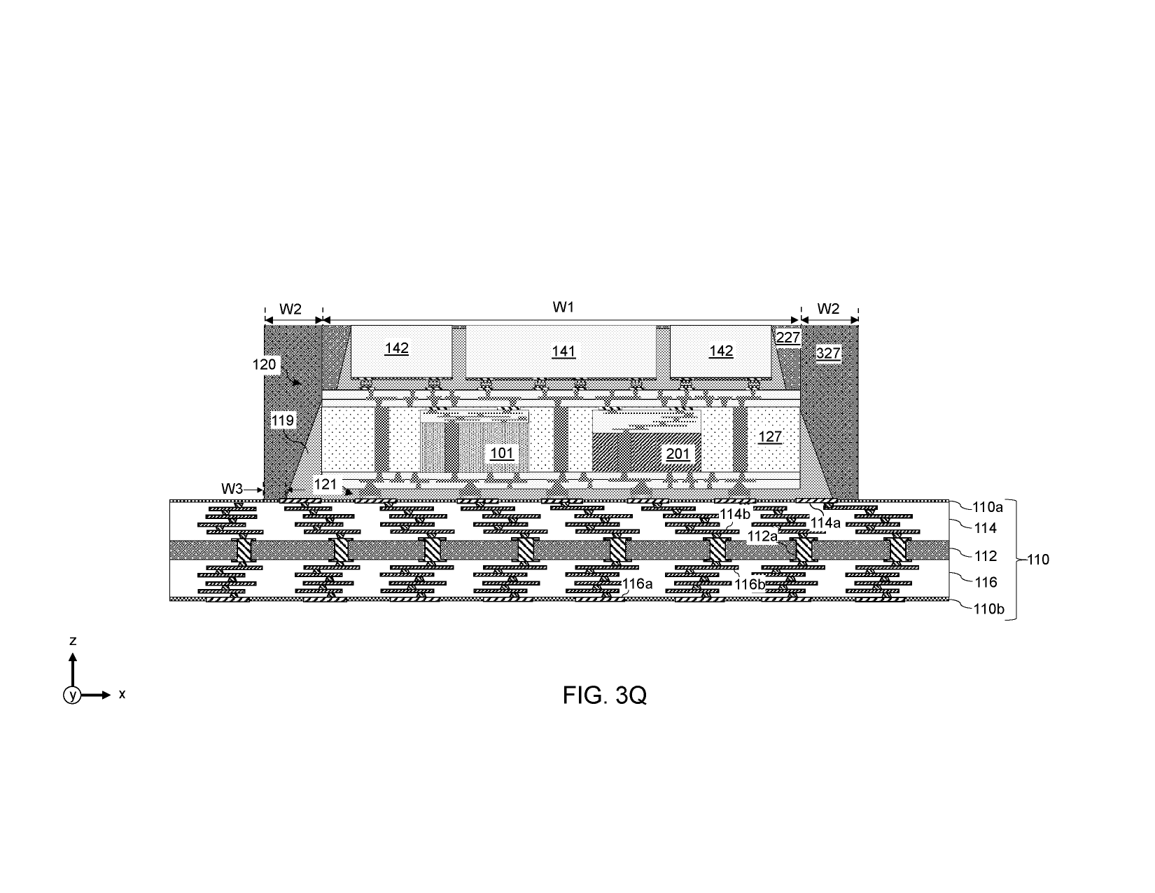

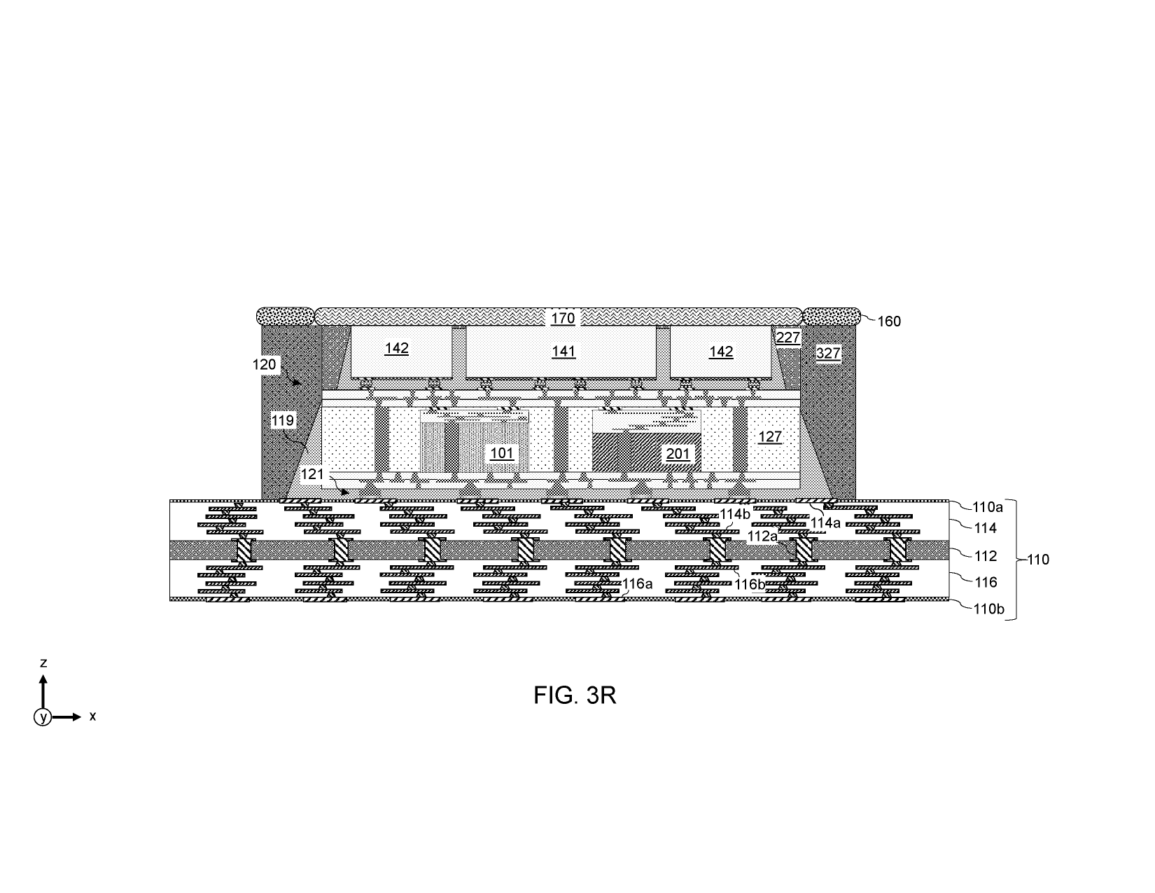

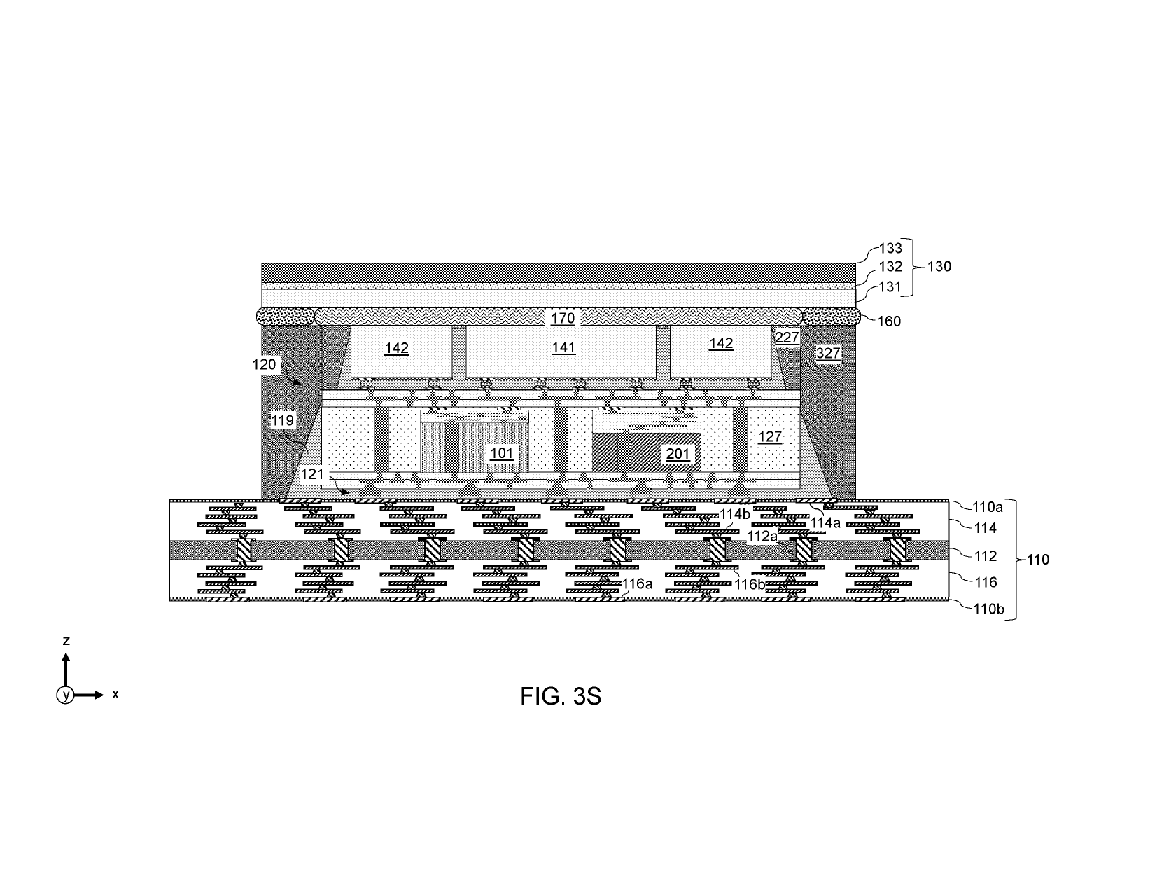

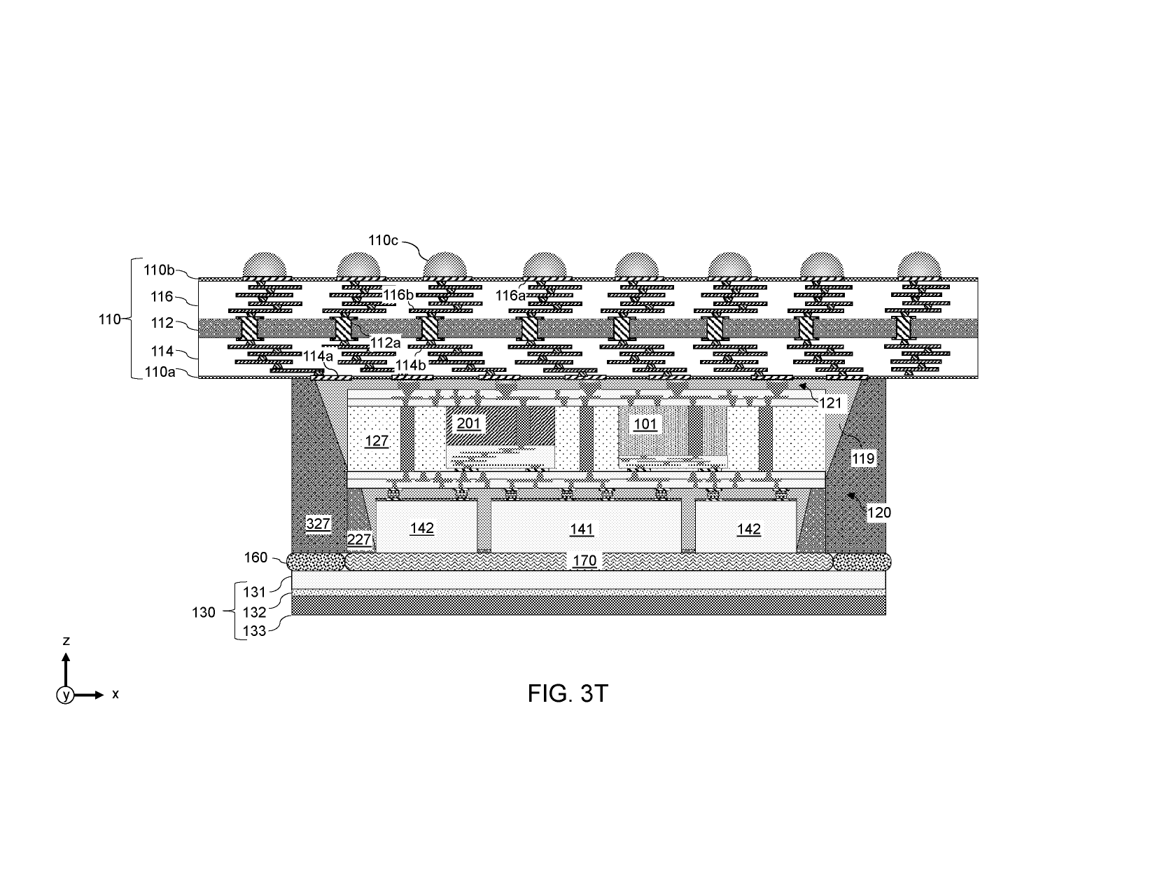

FIGS. 3A-3S illustrate various intermediate structures in a method of forming the package structure 100 according to one or more embodiments. FIG. 3A is a vertical cross-sectional view of an intermediate structure including the TIVs 123 on a first carrier substrate 1 (e.g., carrier wafer) according to an embodiment of the present invention.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used. In at least one embodiment, the carrier substrate 1 may include sapphire or glass and have a thickness of about 1000 µm.

An adhesive layer (e.g., die attach film (DAF); not shown) may be applied to the top surface of the first carrier substrate 1. The adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. For example, the LTHC layer may include Light-To-Heat Conversion Release Coating (LTHC) ink™ that may be commercially available. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150°C to 400°C. Other suitable thermally decomposing adhesive materials that decompose at other temperatures are within the contemplated scope of disclosure.

The TIVs 123 may formed in one or more electroplating processes. In one or more embodiments, a seed layer (not shown) may be formed on the carrier substrate 1. A metal material may then be electroplated on the seed layer to form the TIVs 123. In at least one embodiment, the TIVs 123 may be formed to have a thickness in a range from about 120 µm to 160 µm (e.g., about 140 µm). The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials as well as other suitable formations processes are within the contemplated scope of disclosure.

FIG. 3B is a vertical cross-sectional view of an intermediate structure including the interconnect dies 10 on the first carrier substrate 1 according to an embodiment of the present invention. The LSI die 101 and LRI die 201 may be placed on the first carrier substrate 1. In at least one embodiment, the LSI die 101 and LRI die 201 may be placed on the first carrier substrate 1 using an electromechanical pick-and-place (PNP) machine. As illustrated in FIG. 3B, a height of the LSI bonding pads 104 and LRI bonding pads 204 may be substantially the same as a height of the TIVs 123. The LSI die 101 and LRI die 201 may adhere to the first carrier substrate 1 by the adhesive layer (e.g., DAF; not shown).

FIG. 3C is a vertical cross-sectional view of an intermediate structure including the lower molding material layer 127 according to one or more embodiments. After the LSI die 101 and LRI die 201 are placed on the first carrier substrate 1, the lower molding material layer 127 (e.g., encapsulant layer) may be formed by a specialized molding process (e.g., A3+ molding process). The molding process may include, for example, preparing the molding compound (e.g., e.g., by mixing resin, hardener, fillers, and additives) and injecting (or depositing by spray coating, spin coating or other suitable method) the molding compound into a mold cavity around the LSI die 101 and LRI die 201. The molding compound may include an epoxy polymer material (e.g., an epoxy molding compound (EMC)). In at least one embodiment, the molding compound may be formed on the first carrier substrate 1 and fill in the gaps between the LSI die 101, LRI die 201 and the TIVs 123. The molding compound may encapsulate (e.g., in the x-direction, y-direction and z-direction) the LSI die 101, LRI die 201 and the TIVs 123. The molding process may further include curing the mold compound to achieve desired mechanical and thermal properties, and post-mold processing such as trimming, testing, etc.

As illustrated in FIG. 3C, the lower molding material layer 127 may be formed to have a thickness greater than a height of the TIVs 123 and a height of the LSI bonding pads 104 and the LRI bonding pads 204. In at least one embodiment, the lower molding material layer 127 may be formed to have a thickness in a range from about 170 µm to 210 µm (e.g., about 190 µm).

FIG. 3D is a vertical cross-sectional view of an intermediate structure after polishing (e.g., planarizing) the lower molding material layer 127 according to one or more embodiments. After the lower molding material layer 127 has cured, a planarization process may then be used to make an upper surface of the lower molding material layer 127 substantially coplanar with an upper surface of the LSI die 101, an upper surface of the LRI die 201 and an upper surface of the TIVs 123. In particular, the planarization process may be performed on the upper surface of the lower molding material layer 127 to expose the upper surface of the LSI bonding pads 104, the upper surface of the LRI bonding pads 204 and the upper surface of the TIVs 123. In at least one embodiment, the planarization process may be performed until a thickness of the lower molded portion 120B is in a range from 110 µm to 150 µm (e.g., about 129 µm). The planarization process may include, for example, a mechanical grinding process and/or a CMP process. This may complete the formation of the lower molded portion 120B of the package module 120.

FIG. 3E is a vertical cross-sectional view of an intermediate structure including the upper RDL structure 120C according to one or more embodiments. The upper RDL structure 120C may be formed by alternately forming the plurality of dielectric layers 13 and plurality of redistribution layers 13a on the lower molded portion 120B. Each dielectric layer 13 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 13 may then be patterned by a photolithographic process to form via holes in the dielectric layer 13. The photolithographic process may include forming a patterned photoresist mask (e.g., BL301; not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 13a (e.g., metal traces and metal vias) may be formed on the dielectric layer 13. The redistribution layer 13a may be formed, for example, by depositing (e.g., by CVD, PVD or other suitable deposition technique) one or more layers of metal material such as copper, aluminum, nickel, titanium, a combination thereof or other suitable metals, on the dielectric layer 13 and in the vias holes formed by patterning the dielectric layer 13. The redistribution layer 13a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 3E, the bonding pads 214 may be formed on the uppermost dielectric layer 13. The bonding pads 214 may include a metallic material that may be bonded to a solder material. The bonding pads 214 may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the bonding pads 214. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

FIG. 3F is a vertical cross-sectional view of an intermediate structure including the semiconductor dies 140 on the upper RDL structure 120C according to one or more embodiments. The semiconductor dies 140 may be mounted concurrently on the upper RDL structure 120C in the same process.

The semiconductor dies 140 (including microbump portions) may be positioned over the upper RDL structure 120C using an electromechanical PNP machine. Each of the semiconductor dies 140 may be bonded to the upper RDL structure 120C by one or more of the microbumps 219. In at least one embodiment, the microbumps 219 may include a two-dimensional array of microbumps 219, and each of the semiconductor dies 140 may be attached to the bonding pads 214 by C2 bonding, (e.g., solder bonding). A C2 bonding process that reflows the solder portions of the microbumps 219 may be performed after the microbumps 219 on the semiconductor dies 140 are disposed over corresponding bonding pads 214 on the upper surface of the upper RDL structure 120C.

FIG. 3G is a vertical cross-sectional view of an intermediate structure including the package module underfill layer 129 according to one or more embodiments. The package module underfill layer 129 may be applied by depositing and/or injecting an epoxy-based polymeric material (e.g., U19T) onto the upper RDL structure 120C. The epoxy-based polymeric material may be applied on the lower molded portion 120B so as to be formed under the semiconductor dies 140 and around the microbumps 219. In at least one embodiment, the epoxy-based polymeric material may fill substantially all of the gaps between the semiconductor dies 140 and the lower molded portion 120B. The package module underfill layer 129 may then be cured, for example, in a box oven for about 90 minutes at about 150°C to provide the package module underfill layer 129 with a sufficient stiffness and mechanical strength.

FIG. 3H is a vertical cross-sectional view of an intermediate structure including the upper molding material layer 227 according to one or more embodiments. The upper molding material layer 227 may be formed by dispensing a liquid molding material (e.g., EMC, epoxy molding material, A7 molding compound, etc.) onto the intermediate structure of FIG. 3G by a suitable dispensing tool. The upper molding material layer 227 may be dispensed onto the intermediate structure to have a height greater than the height of the upper surface 140a of the semiconductor dies 140. The semiconductor dies 140 may have a thickness, for example, in a range of about 400 µm to 1000 µm (e.g., about 692 µm).

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the upper RDL structure 120C, sizes of the semiconductor dies 140, etc.

In at least one embodiment, the molding material of the upper molding material layer 227 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the upper molding material layer 227. In at least one embodiment, the upper molding material layer 227 may be substantially free of voids.

FIG. 3I is a vertical cross-sectional view of an intermediate structure after polishing (e.g., planarizing) the upper molding material layer 227 according to one or more embodiments. After the upper molding material layer 227 has been adequately cured, the upper molding material layer 227 may be planarized so as to make the upper surface of the upper molding material layer 227 to be substantially coplanar with the semiconductor die upper surface 140a. The upper molding material layer 227 may be planarized, for example, by grinding, chemical mechanical polishing (CMP) or other suitable planarization technique. This may complete formation of the upper molded portion 120D of the package module 120.

FIG. 3J is a vertical cross-sectional view of an intermediate structure including a second carrier substrate 2 on the upper molded portion 120D according to one or more embodiments. The second carrier substrate 2 may be substantially the same as the first carrier substrate 1 (e.g., having a thickness of about 550 µm). The second carrier substrate 2 may include an adhesive layer (e.g., DAF; not shown) which may help the second carrier substrate 2 to the upper molded portion 120D. The adhesive layer may be substantially similar to the adhesive layer used on the first carrier substrate 1.

FIG. 3K is a vertical cross-sectional view of an intermediate structure including the lower RDL structure 120A according to one or more embodiments. As illustrated in FIG. 3K, after the second carrier substrate 2 is placed on the upper molded portion 120D, the intermediate structure of FIG. 3J may be inverted and the first carrier substrate 1 may be detached from the lower molded portion 120B. The first carrier substrate 1 may be detached from the lower molded portion 120B, for example, by deactivating the adhesive layer (e.g., DAF; not shown) adhering the first carrier substrate 1 to the lower molded portion 120B. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

After the first carrier substrate 1 is detached from the lower molded portion 120B, a backside of the lower molded portion 120B including the lower molding material layer 127 may be planarized (e.g., by grinding, CMP, etc.) to expose a backside of the TIVs 123, a backside of the through vias 106 in the LSI die 101 and through vias 206 in the LRI dies 201. The lower RDL structure 120A may then be formed on the lower molded portion 120B. The lower RDL structure 120A may be formed in a manner substantially similar to the manner of forming the upper RDL structure 120C (e.g., see FIG. 3E and associated text).

After the lower RDL structure 120A is formed, the C4 bumps 121 may be formed on the lower RDL structure 120A. The C4 bumps 121 may include, for example, a metal pillar (e.g., copper pillar) formed, for example, by an electroplating process. Solder bumps may then be formed on the metal pillar. The solder may be formed on the metal pillar, for example, by one or more processes including ball mounting, electroplating, solder printing, solder immersion and solder injection.

FIG. 3L is a vertical cross-sectional view of an intermediate structure on a frame mount 300 according to one or more embodiments. After the C4 bumps 121 are formed on the lower RDL structure 120A, the intermediate structure may be inverted and placed on a frame mount 300. In particular, the C4 bumps 121 may contact an upper surface of the frame mount 300. The frame mount 300 may provide physical support to the intermediate structure and ensure that the intermediate structure is securely held in place during the fabrication process.

FIG. 3M is a vertical cross-sectional view of an intermediate structure after removing the second carrier substrate 2 according to one or more embodiments. The second carrier substrate 2 may be detached (e.g., debonded) from the upper molded portion 120D in a manner substantially similar to the manner in which the first carrier substrate 1 was detached from the lower molded portion 120B. In particular, the second carrier substrate 2 may be detached by deactivating the adhesive layer (e.g., DAF; not shown) adhering the second carrier substrate 2 to the upper molded portion 120D. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

FIG. 3N is a vertical cross-sectional view of an intermediate structure after remounting the intermediate structure on the frame mount 300 according to one or more embodiments. As illustrated in FIG. 3N, after the second carrier substrate 2 is detached, the intermediate structure may be inverted and remounted on the frame mount 300. In particular, the intermediate structure may be mounted on the frame mount 300 such that the upper molded portion 120D contacts an upper surface of the frame mount 300. The C4 bumps 121 may then be cleaned to remove any adhesive material from the adhesive layer (e.g., DAF).

After the C4 bumps 121 are cleaned, a singulation process (e.g., dicing, sawing, etc.) may be performed. The singulation process may separate the package module 120 from surrounding wafer material and complete the formation of the package module 120.

FIG. 3O is a vertical cross-sectional view of an intermediate structure including the package module 120 on the package substrate 110 according to one or more embodiments. After the singulation process is performed, the package module 120 may be mounted on the package substrate 110. In at least one embodiment, an electromechanical PNP machine may be used to position the package module 120 over the package substrate 110. The electromechanical PNP machine may then lower the package module 120 onto the package substrate 110 so that the C4 bumps 121 contact the package substrate upper bonding pads 114a. A reflow process may then be performed to cause a reflow of the solder in the C4 bumps 121. The package module 120 may thereby be electrically coupled to the package substrate 110.

FIG. 3P is a vertical cross-sectional view of an intermediate structure including the package underfill layer 119 according to one or more embodiments. The package underfill layer 119 may be applied by depositing and/or injecting an epoxy-based polymeric material onto the package substrate 110. The epoxy-based polymeric material may be applied on the package substrate 110 and spread (e.g., by capillary action) under the package module 120 and around the C4 bumps 121. In at least one embodiment, the epoxy-based polymeric material may fill substantially all of the gaps between the package module 120 and the package substrate 110. The epoxy-based polymeric material may then be cured, for example, in a box oven for about 90 minutes at about 150°C to provide the package underfill layer 119 with a sufficient stiffness and mechanical strength.

FIG. 3Q is a vertical cross-sectional view of an intermediate structure including the outer molding material layer 327 according to one or more embodiments. After the package underfill layer 119 has cured, the outer molding material layer 327 may be formed around an outside of the package module 120. The outer molding material layer 327 may be formed in a manner similar to the manner of forming the upper molding material layer 227 (e.g., see FIG. 3H and associated text).

In particular, the outer molding material layer 327 may be formed by dispensing a liquid molding material (e.g., EMC, epoxy molding material, A7 molding compound, etc.) onto the intermediate structure of FIG. 3P by a suitable dispensing tool. In at least one embodiment, the outer molding material layer 327 may be dispensed onto the intermediate structure to have a height greater than a height of the package module 120 (e.g., greater than the height of the upper surface 140a of the semiconductor dies 140 and the upper surface of the upper molding material layer 227). A planarization process may then be used to make an upper surface of the outer molding material layer 327 substantially coplanar with an upper surface of the package module 120.

As illustrated in FIG. 3Q, the outer molding material layer 327 may be formed to have a width W3 at the package substrate 110. The width W3 may be less than the width W2 of the outer molding material layer 327. In at least one embodiment, the width W3 may be in a range from 10% to 50% of the width W2 of the outer molding material layer 327.

FIG. 3R is a vertical cross-sectional view of an intermediate structure including the TIM layer 170 and adhesive layer 160 according to one or more embodiments. After the outer molding material layer 327 has cured, the TIM layer 170 may be formed on the package module 120. In at least one embodiment, an thermally conductive adhesive layer (not shown) may be formed on the package module 120, and the TIM layer 170 may be adhered to the package module 120 by the thermally conductive adhesive layer.

The adhesive layer 160 may then be formed on the upper surface of the outer molding material layer 327. The adhesive layer 160 may be formed and patterned, for example, by any suitable dispensing technique.

FIG. 3S is a vertical cross-sectional view of an intermediate structure including the package lid 130 according to one or more embodiments. The package lid 130 may be assembled at some point prior to attaching the package lid 130 on the intermediate structure of FIG. 3R. The package lid 130 may be assembled, for example, by applying (e.g., by spraying, coating or other suitable application process) the bonding layer 135 (e.g., thermally conductive adhesive) to an upper surface of the bottom lid portion 130B, and pressing the top lid portion 130A onto the bonding layer 135. The top lid portion 130A may then be clamped to the bottom lid portion 130B until the bonding layer 135 is set.

After the package lid 130 has been assembled, the package lid 130 may be pressed onto the TIM layer 170 and adhesive layer 160. The package lid 130 may then be clamped together with package module 120 and the package substrate 110 for a period to allow the adhesive layer 160 to cure and form a secure bond between the package lid 130 and the outer molding material layer 327. The clamping may be performed, for example, by using a heat clamp module. The heat clamp module may apply a uniform force across the upper surface of the package lid 130.

FIG. 3T is a vertical cross-sectional view of an intermediate structure including the solder balls 110c of the BGA according to one or more embodiments.

After the adhesive layer 160 has adequately cured, the intermediate structure may be inverted and the solder balls 110c of the BGA may be formed on the board-side surface of the package substrate 110. The solder balls 110c may be formed, for example, by one or more processes including ball mounting, electroplating, solder printing, solder immersion and solder injection. The forming of the solder balls 110c may complete the formation of the package structure 100.

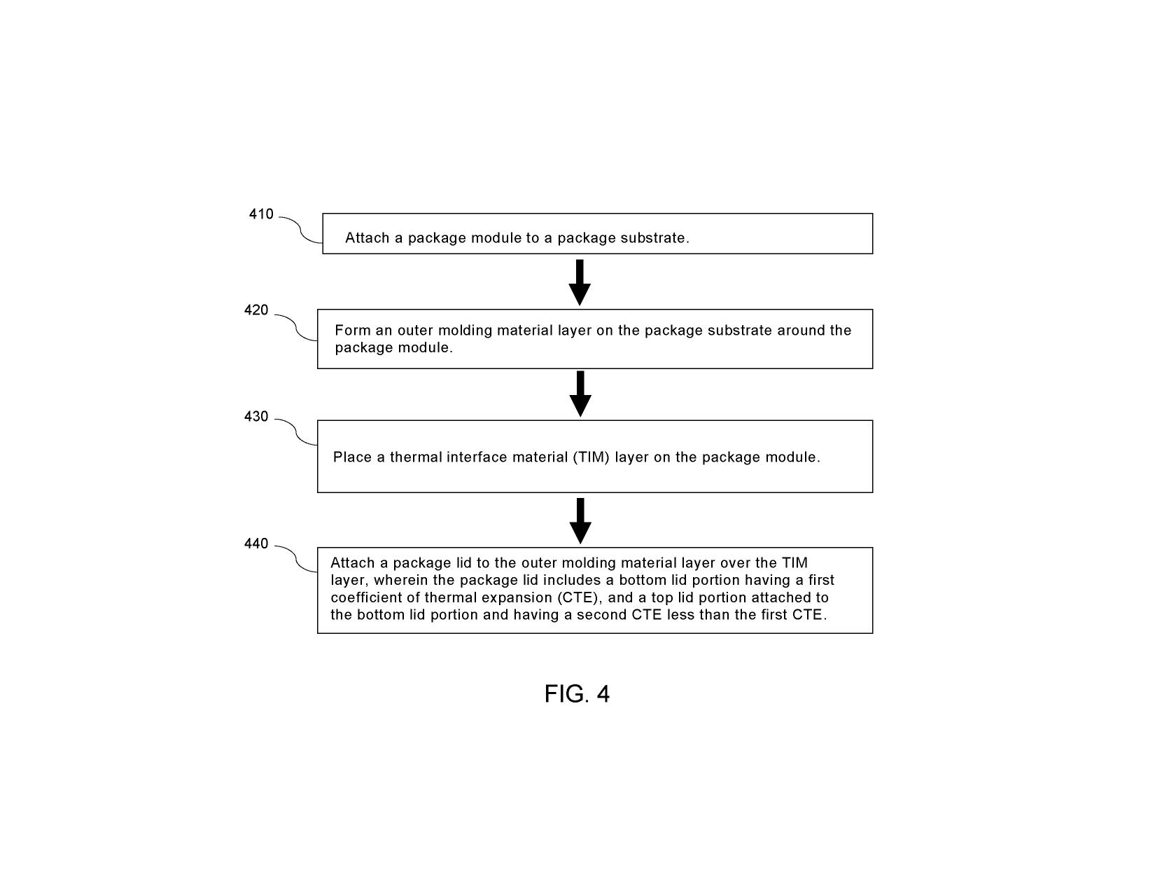

FIG. 4 is a flow chart illustrating a method of making the package structure 100 according to one or more embodiments. Step 410 includes attaching a package module to a package substrate. Step 420 includes forming an outer molding material layer on the package substrate around the package module. Step 430 includes placing a thermal interface material (TIM) layer on the package module. Step 440 includes attaching a package lid to the outer molding material layer over the TIM layer, wherein package lid includes a bottom lid portion having a first coefficient of thermal expansion (CTE), and a top lid portion attached to the bottom lid portion and having a second CTE less than the first CTE.

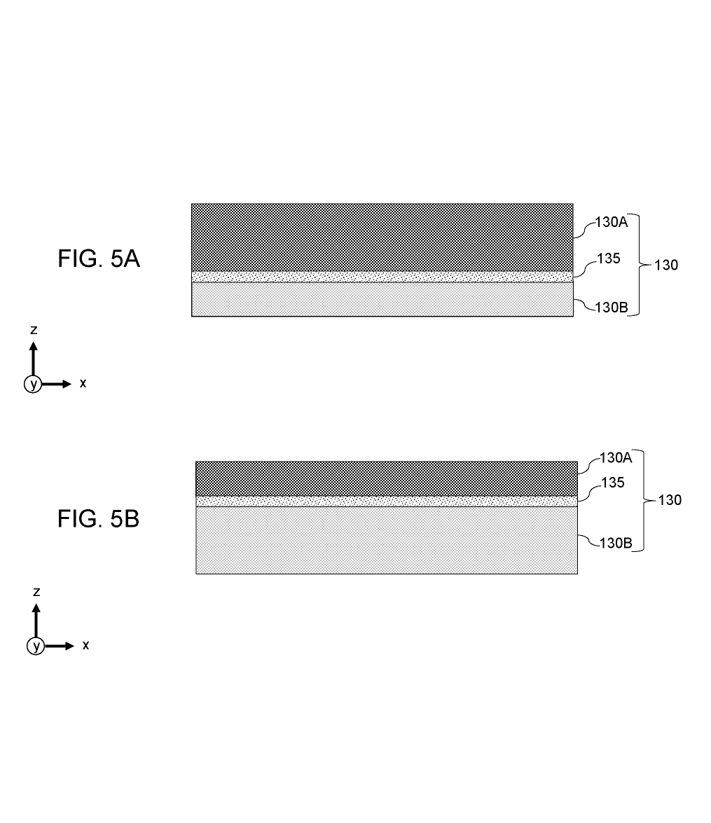

FIGS. 5A-5B are vertical cross-sectional views of the package lid 130 having alternative designs according to one or more embodiments. FIG. 5A is a vertical cross-sectional view of the package lid 130 having a first alternative design according to one or more embodiments. As illustrated in FIG. 5A, the package lid 130 having the first alternative design may be substantially the same as the package lid 130 in FIGS. 1A-1C. However, in the first alternative design, a thickness of the top lid portion 130A may be substantially greater than a thickness of the bottom lid portion 130B in order to control a morphology of the package lid 130 to match a CoW die warp profile. This design may help to reduce thermal stress (e.g., reduce lid warp and die warp) induced by the package lid 130 at room temperature, high temperature and low temperature. In at least one embodiment, the thickness of the top lid portion 130A may be at least three times the thickness of the bottom lid portion 130B. In at least one embodiment, the thickness of the top lid portion 130A may be about 1.5mm and the thickness of the bottom lid portion 130B may be about 0.5mm.

FIG. 5B is a vertical cross-sectional view of the package lid 130 having a second alternative design according to one or more embodiments. As illustrated in FIG. 5B, the package lid 130 having the second alternative design may be substantially the same as the package lid 130 in FIGS. 1A-1C. However, in the second alternative design, a thickness of the top lid portion 130A may be substantially less than a thickness of the bottom lid portion 130B in order to control a morphology of the package lid 130 to match a CoW die warp profile. This design may help to reduce thermal stress (e.g., reduce lid warp and die warp) induced by the package lid 130 at room temperature, high temperature and low temperature. In at least one embodiment, the thickness of the bottom lid portion 130B may be at least three times the thickness of the top lid portion 130A. In at least one embodiment, the thickness of the top lid portion 130A may be about 0.5mm and the thickness of the bottom lid portion 130B may be about 1.5 mm.

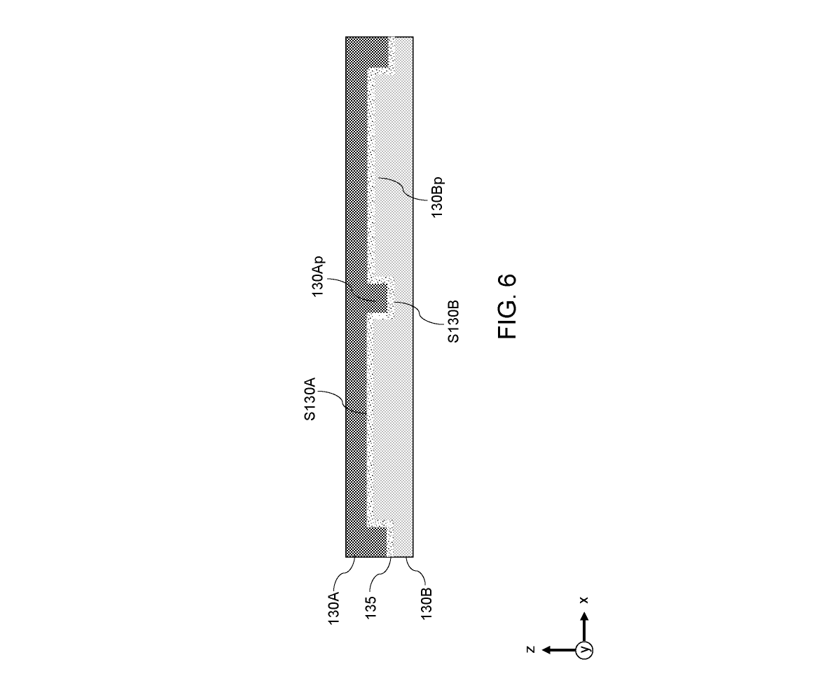

FIG. 6 is a perspective view of the package lid 130 having a third alternative embodiment design according to one or more embodiments. The package lid 130 having the third alternative design may be substantially the same as the package lid 130 in FIGS. 1A-1C. However, in the third alternative embodiment design, at least one of the top lid portion 130A or the bottom lid portion 130B may be patterned package lid 130 in order to control a morphology of the package lid 130 to match a CoW die warp profile.

In at least one embodiment, an upper surface S130B of the bottom lid portion 130B may include a patterned surface and a lower surface S130A of the top lid portion 130A may include a patterned surface. The upper surface S130B and lower surface S130A may be patterned, for example, using a computer numerical control (CNC) machine. The CNC machine may pattern the upper surface S130B and lower surface S130A by at least one of cutting, milling, drilling, and engraving. The CNC machine may be programmed via computer software to follow precise instructions for shaping and creating intricate components in the pattern of the upper surface S130B and the pattern of the lower surface S130A. In least one embodiment, the computer software may employ one or more artificial intelligence programs in designing the pattern (e.g., a custom pattern) of the upper surface S130B and the pattern (e.g., a custom pattern) of the lower surface S130A.

The pattern of the upper surface S130B and the pattern of the lower surface S130A may be designed based on the CoW die warp profile. In particular, the pattern of the upper surface S130B and the pattern of the lower surface S130A may be used to manipulate a percentage of the package lid 130 occupied by the top lid portion 130A or the bottom lid portion 130B and, thereby, manipulate a CTE of the package lid 130.

In particular, the lower surface S130A of the top lid portion 130A may include one or more projections 130Ap and the upper surface S130B of the bottom lid portion 130B may include one or more projections 130Bp. The projections 130Ap of the top lid portion 130A may have an interlocking (e.g., interdigitated) arrangement with the projections 130Bp of the bottom lid portion 130B. The patterned upper surface S130B of the bottom lid portion 130B and the patterned lower surface S130A of the top lid portion 130A may be designed to control a local curvature of the package lid 130.

In at least one embodiment, a patterning in the package lid 130 may use projections and/or recesses to manipulate a percentage of the package lid 130 occupied by the top lid portion 130A or the bottom lid portion 130B. An overall CTE (e.g., average CTE) of the package lid 130 may be increased by increasing the number and/or size of projections (e.g., volume of projections) in the upper surface S130B of the bottom lid portion 130B and/or increasing the number and/or size of recesses (e.g., volume of recesses) in the lower surface S130A of the top lid portion 130A. On the other hand, the overall CTE of the package lid 130 may be decreased by increasing the number and/or size of projections in the lower surface S130A of the top lid portion 130A and/or increasing the number and/or size of recesses in the upper surface S130B of the bottom lid portion 130B.

As illustrated in the third alternative design in FIG. 6, a volume of the total package lid 130 occupied by the projections 130Bp may be greater than a volume of the total package lid 130 occupied by the projections 130Ap. Therefore, a CTE of the package lid 130 in the third alternative design in FIG. 6 may be greater than a CTE of the package lid 130 in FIGS. 1A-1C where the top lid portion 130A and the bottom lid portion 130B have substantially the same thickness.

It should also be noted that a location of the projections may correspond to particular locations in the package structure 100. For example, a projection 130Ap in the top lid portion 130A may be located at a location in the package structure 100 where a low CTE is recommended to match a CoW die warp profile. On the other hand, a projection 130Bp in the bottom lid portion 130B may be located at a location in the package structure 100 where a high CTE is recommended to match a CoW die warp profile.

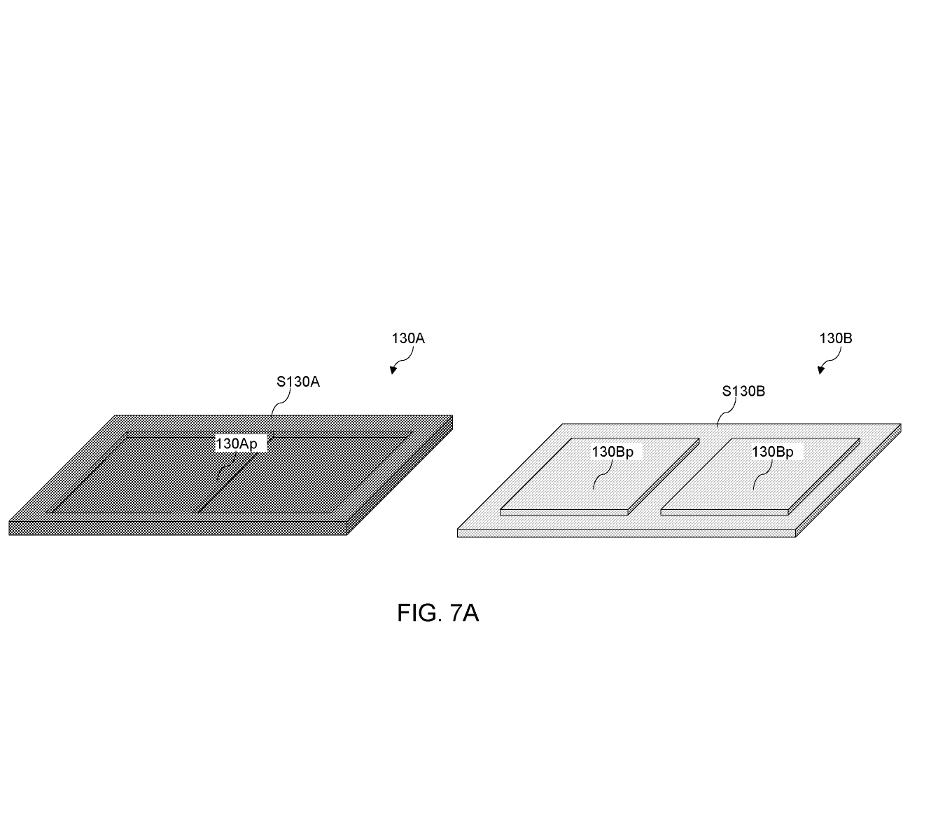

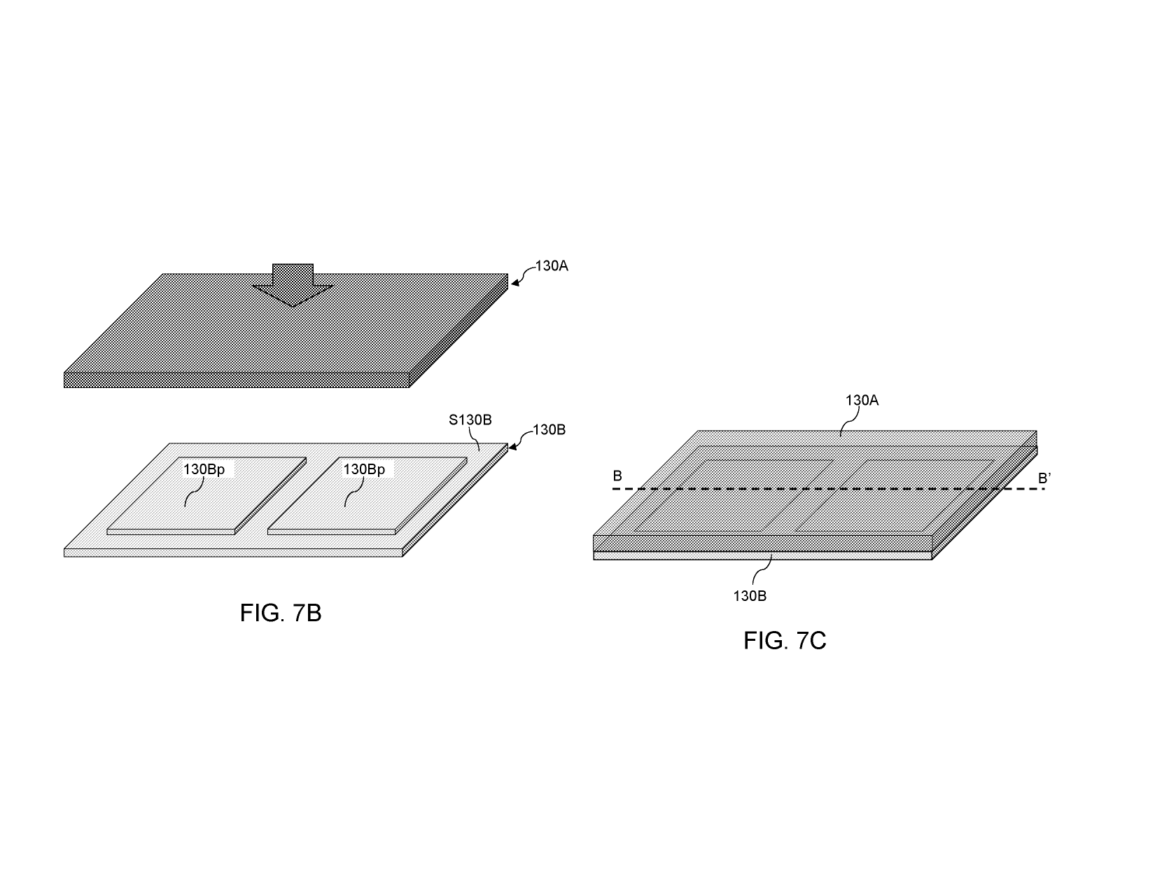

FIGS. 7A-7C are perspective views of intermediate structures in a method of making (e.g., assembling) the package lid 130 having the third alternative design according to one or more embodiments. FIG. 7A is a perspective view of the top lid portion 130A and the bottom lid portion 130B prior to assembly according to one of more embodiments.

FIG. 7B is a perspective view of the top lid portion 130A positioned over the bottom lid portion 130B prior to assembly according to one of more embodiments. In at least one embodiment, an electromechanical PNP machine may be used to position the top lid portion 130A over the bottom lid portion 130B. The bonding layer 135 may be formed (e.g., by spin coating, spraying or other suitable process) on the bottom lid portion 130B (or top lid portion 130A) prior to assembly.

FIG. 7C is a perspective view of the assembled package lid 130 including the top lid portion 130A and bottom lid portion 130B prior to assembly according to one of more embodiments. The bonding layer 135 has been omitted from FIG. 7C for ease of understanding. The vertical cross-sectional view in FIG. 6 is the view along line B-B’ in FIG. 7C.

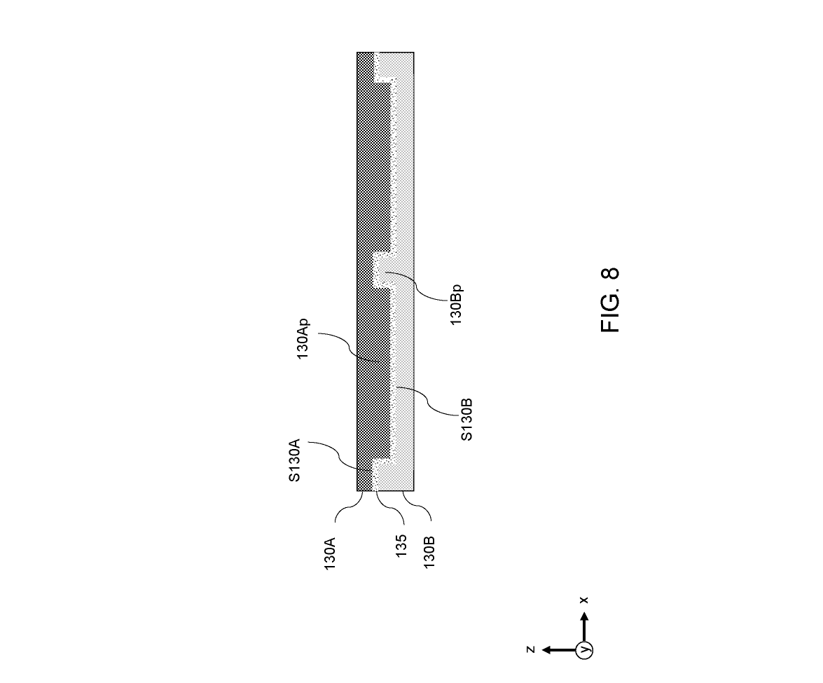

FIG. 8 is a vertical cross-sectional view of the package lid 130 having a fourth alternative embodiment design according to one or more embodiments. The package lid 130 having the fourth alternative design may be substantially the same as the package lid 130 having the third alternative design in FIG. 6. However, the package lid 130 having the fourth alternative design may be considered to be an inversion of the package lid 130 having the third alternative design in FIG. 6.

As in the third alternative embodiment design in FIG. 6, in the fourth alternative embodiment design in FIG. 8, the lower surface S130A of the top lid portion 130A and the upper surface S130B of the bottom lid portion 130B may be patterned so that a warp profile of the package lid 130 may match a CoW die warp profile at room temperature, high temperature and low temperature. In particular, in the fourth alternative design of FIG. 8, the lower surface S130A of the top lid portion 130A may include one or more projections 130Ap and the upper surface S130B of the bottom lid portion 130B may include one or more projections 130Bp. However, in the fourth alternative design in FIG. 8, a volume of the total package lid 130 occupied by the projections 130Ap may be greater than a volume of the total package lid 130 occupied by the projections 130Bp. Therefore, a CTE of the package lid 130 (e.g., overall CTE of the package lid 130) in the fourth alternative design in FIG. 8 may be lower than a CTE of the package lid 130 in the third alternative design in FIG. 6.

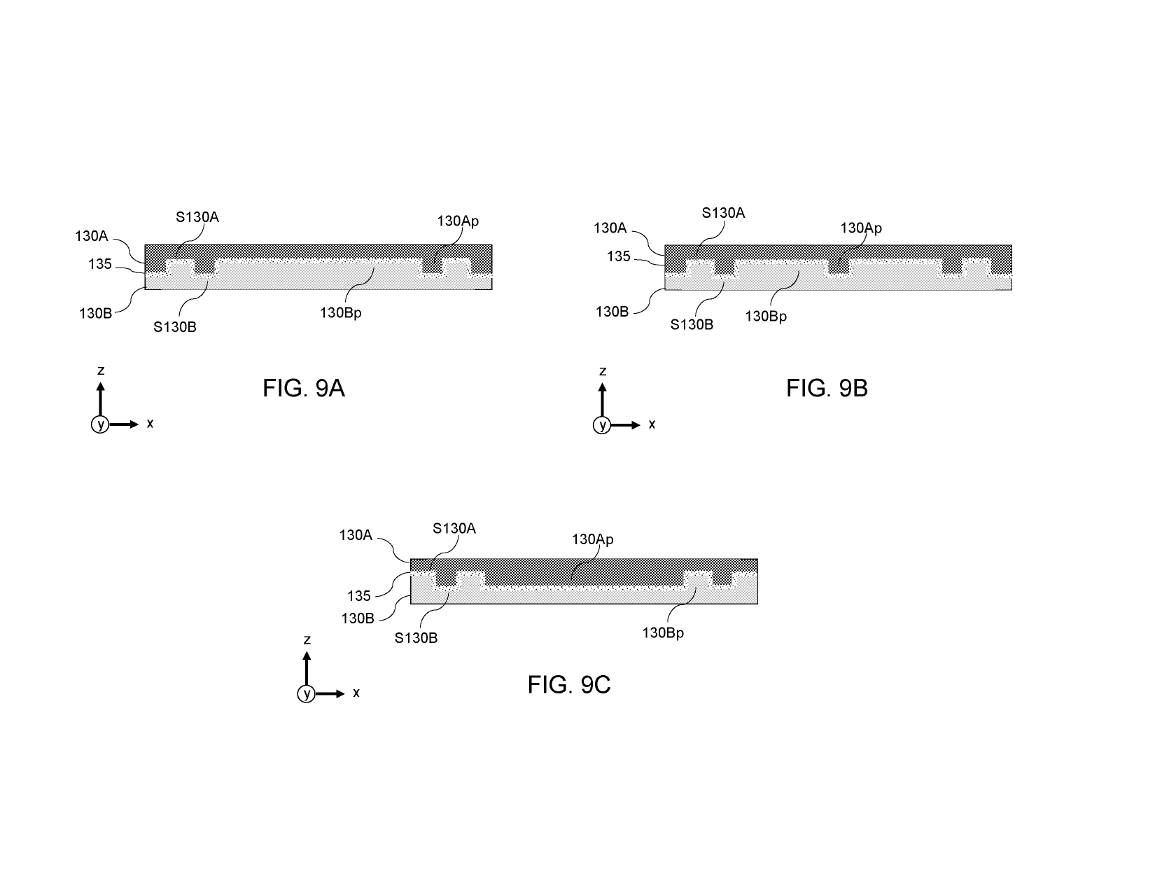

FIGS. 9A-9C are vertical cross-sectional views of the package lid 130 having additional alternative embodiment designs according to one or more embodiments. In the additional alternative designs of FIGS. 9A-9C, the lower surface S130A (e.g., patterned surface) of the top lid portion 130A may again include one or more projections 130Ap and the upper surface S130B (e.g., patterned surface) of the bottom lid portion 130B may again include one or more projections 130Bp, so that a warp profile of the package lid 130 may match a CoW die warp profile at room temperature, high temperature and low temperature.

FIG. 9A is a vertical cross-sectional view of the package lid 130 having a fifth alternative design according to one of more embodiments. In the fifth alternative design in FIG. 9A, the top lid portion 130A may have a low stiffness pattern (e.g., relatively low volume of projections 130Ap) and the bottom lid portion 130B may have a high stiffness pattern (e.g., relatively high volume of projections 130Bp).

FIG. 9B is a vertical cross-sectional view of the package lid 130 having a sixth alternative design according to one of more embodiments. In the sixth alternative design in FIG. 9B, the top lid portion 130A may have a medium stiffness pattern (e.g., relatively moderate volume of projections 130Ap) and the bottom lid portion 130B may have a high stiffness pattern (e.g., relatively high volume of projections 130Bp).

FIG. 9C is a vertical cross-sectional view of the package lid 130 having a seventh alternative design according to one of more embodiments. In the seventh alternative design in FIG. 9C, the top lid portion 130A may have a high stiffness pattern (e.g., relatively high volume of projections 130Ap) and the bottom lid portion 130B may have a low stiffness pattern (e.g., relatively low volume of projections 130Bp).

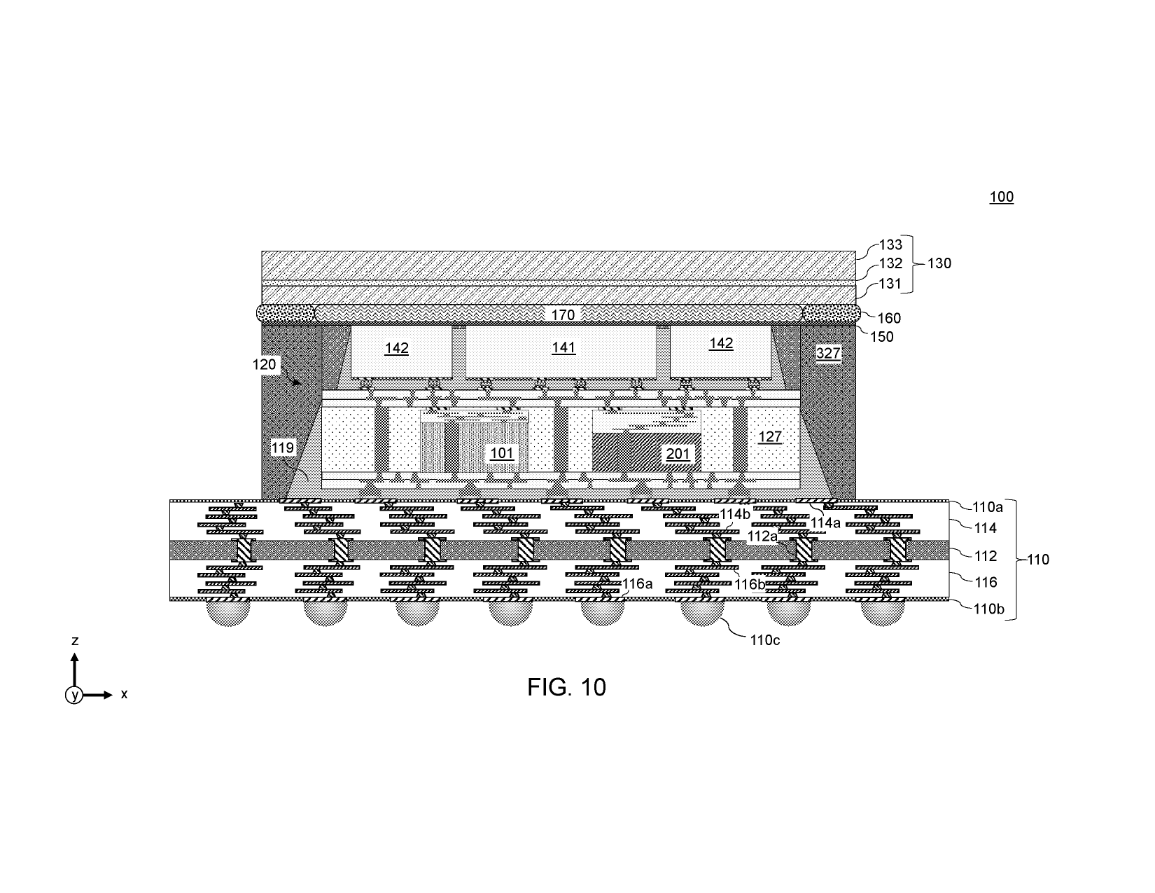

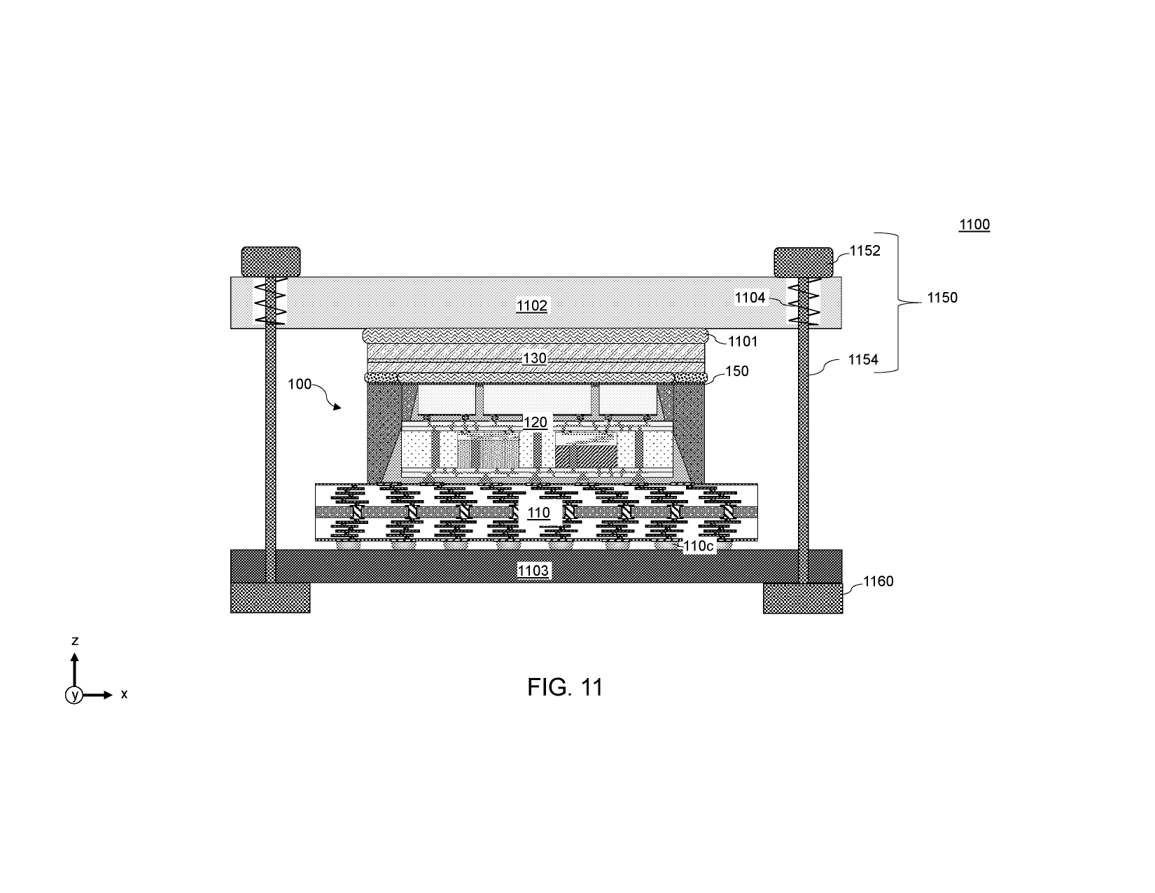

FIG. 10 is a vertical cross-sectional view of the package structure 100 having a first alternative embodiment design according to one of more embodiments. As illustrated in FIG. 10, the first alternative embodiment design of the package structure 100 may be substantially the same as the package structure 100 in FIGS. 1A-1C. However, in the first alternative embodiment design in FIG. 10, the package structure 100 may include a backside metal layer 150 on the upper surface of the package module 120 and an upper surface of the outer molding material layer 327. The backside metal layer 150 may cover substantially the entire upper surface of the package module 120 and substantially the entire upper surface of the outer molding material layer 327. In at least one embodiment, the TIM layer 170 may be attached to the package module 120 through the backside metal layer 150 and the adhesive layer 160 may be attached to the outer molding material layer 327 through the backside metal layer 150. In at least one embodiment, the backside metal layer 150 may be patterned to cover less than an entirety of the upper surface of the package module 120 and/or less than an entirety of the upper surface of the outer molding material layer 327.

The backside metal layer 150 may have a substantially uniform thickness throughout. In at least one embodiment, the backside metal layer 150 may have a thickness in a range from 0.1 µm to 1.5 µm. The backside metal layer 150 may include, for example, one or more layers of metal material such as copper, aluminum, nickel, titanium, a combination thereof or other suitable metals. In at least one embodiment, the backside metal layer 150 may include one or more layers of aluminum, titanium, nickel vanadium (NiV) and gold.

The backside metal layer 150 may be formed by conformally depositing (e.g., by CVD, PVD or other suitable deposition technique) a metal material on the upper surface of the package module 120 and/or the upper surface of the outer molding material layer 327. In at least one embodiment, the metal material may be deposited by a sputtering process. The metal material may then optionally be patterned (e.g., etched) by a photolithographic process to form the backside metal layer 150. The photolithographic process may include forming a patterned photoresist mask (not shown) on the metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

FIG. 11 is a vertical cross-sectional view of a semiconductor device 1100 according to one of more embodiments. As illustrated in FIG. 11, the semiconductor device 1100 may include the package structure 100 with the backside metal layer 150.

The semiconductor device 1100 may also include an upper TIM layer 1101 on an upper surface of the package lid 130. An upper surface of the top lid portion 130A of the package lid 130 may contact a lower surface of the upper TIM layer 1101. The upper TIM layer 1101 may be substantially the same as the TIM layer 170 (see FIG. 1A). In particular, the TIM layer 1101 may be composed of the same materials as the TIM layer 170

The semiconductor device 1100 may further include a heat sink 1102 on an upper surface of the upper TIM layer 1101. The heat sink 1102 may have a flat plate shape. In at least one embodiment, a substantial entirety of the upper surface of the upper TIM layer 1101 may contact a lower surface of the heat sink 1102. The heat sink 1102 may have a thickness less than a thickness of the package structure 100. The heat sink 1102 may have a length in the x-direction greater than a length of the package structure 100 in the x-direction, and a length in the y-direction greater than a length of the package structure in the y-direction.

The heat sink 1102 may be composed of one or more layers of thermally conductive material such as a metal or metal alloys. In at least one embodiment, the heat sink 1102 may be composed of aluminum, copper, copper alloys, etc. The heat sink 1102 may efficiently dissipate heat away from the package structure 100 through the package lid 130.

As further illustrated in FIG. 11, the package structure 100 may be mounted on a board such as a printed circuit board (PCB) 1103. In at least one embodiment, the package structure 100 may be electrically coupled to the PCB 1103 by the solder balls 110c of the BGA on the board-side surface of the package substrate 110. The PCB 1103 may have a size and shape comparable to the size and shape of the heat sink 1102.

The semiconductor device 1100 may also include a fixing member 1150 for fixing the heat sink 1102 to the PCB 1103. The fixing member 1150 may be tightened to compress the package structure 100 and upper TIM layer 1101 between the heat sink 1102 and the PCB 1103. The fixing member 1150 may include, for example, a screw, bolt, etc.

As illustrated in FIG. 11, in at least one embodiment, the fixing member 1150 may extend through an opening in the heat sink 1102 and an opening in the PCB 1103 and connect to (e.g., by threaded connection) a backplate on a bottom of the PCB 1103. The fixing member 1150 may include a head portion 1152 seated on an upper surface of the heat sink 1102, and a rod portion 1154 connected to the head portion 1152. The rod portion 1154 may extend down from the head portion 1152 and through the heat sink 1102 and the PCB 1103 and connect to the backplate 1160.

The semiconductor device 1100 may also include an urging member 1104 (e.g., spring, rubber ring, etc.) around the rod portion 1154 of the fixing member 1150. When the fixing member 1150 is inserted into the opening, the urging member 1104 may be compressed against a bottom of the opening in the heat sink 1102, and urge the fixing member 1150 upward.

The package lid 130 may help to improve a performance (e.g., thermal performance) of the semiconductor device 1100. In particular, the package lid 130 may help to inhibit die crack during a mounting of the heat sink 1102 on the package structure 100. The package lid 130 may also help to reduce a risk of the upper TIM layer 1101 pumping out by providing a more flattened lid /heat sink contact surface.

Referring now to FIGS. 1A-11, a package structure 100 may include a package substrate 110, a package module 120 on the package substrate 110, an outer molding material layer 327 on the package substrate 110 around the package module 120, a thermal interface material (TIM) layer 170 on the package module 120, and a package lid 130 on the TIM layer 170 and attached to the outer molding material layer 327, including a bottom lid portion 130B having a first coefficient of thermal expansion (CTE), and a top lid portion 130A attached to the bottom lid portion 130B and having a second CTE less than the first CTE.

In embodiment, the package structure 100 may further include a bonding layer 135 on the bottom lid portion 130B and configured to bond the top lid portion 130A to the bottom lid portion 130B. In an embodiment, an outer sidewall of the package lid 130 may be substantially aligned with an outer sidewall of the outer molding material layer 327. In one embodiment, the package structure 100 may further include an adhesive layer 160 on the outer molding material layer 327, wherein the bottom lid portion 130B of the package lid 130 may be attached to the outer molding material layer 327 with the adhesive layer 160. In one embodiment, a thickness of the adhesive layer 160 may be substantially the same as a thickness of the TIM layer 170. In one embodiment, the bottom lid portion 130B may include a patterned upper surface S130B and the top lid portion 130A may include a patterned lower surface S130A having an interlocking arrangement with the patterned upper surface S130B of the bottom lid portion 130B. In an embodiment, the bottom lid portion 130B may include at least one of Cu, Ag, Al, stainless steel, CuAg alloy and CuNi alloy, and the top lid portion 130A may include at least one of Kovar, Invar, Co, Cu/Mo alloy, SiAl, AlN, AlSiN, AlSiC, CuSiC AgD (silver-diamond composite), CuD (copper-diamond composite), diamond substrate (e.g., diamond plate), and Alloy42. In an embodiment, the first CTE of the bottom lid portion 130B may be in a range from 17 to 25 and the second CTE of the top lid portion 130A may be in a range from 1 to 10. In an embodiment, the package module 120 may further include a lower molded portion 120B including an interconnect die 101, 201, and an upper molded portion 120D including a plurality of semiconductor dies 140 interconnected by the interconnect die 101, 201. In an embodiment, the package module 120 may further include a lower redistribution layer structure 120A on a bottom surface of the lower molded portion 120B, and an upper redistribution layer structure 120C on a top surface of the lower molded portion 120B. In an embodiment, the plurality of semiconductor dies 140 may be electrically coupled to the interconnect die 101, 201 through the upper redistribution layer structure 120C, and the interconnect die 101, 201 may be electrically coupled to the package substrate 110 through the lower redistribution layer structure 120A. In an embodiment, the TIM layer 170 may include a metal TIM layer 170. In an embodiment, the package structure 100 may further include a package underfill layer 119 between the package substrate 110 and package module 120 and configured to fix the package module 120 to the package substrate 110. In an embodiment, the package structure 100 may further include a backside metal layer 150 on the package module 120, wherein the TIM layer 170 and the adhesive layer 160 may be on the backside metal layer 150.

Referring again to FIGS. 1A-11, a method of making a package structure 100 may include attaching a package module 120 to a package substrate 110, forming an outer molding material layer 327 on the package substrate 110 around the package module 120, placing a thermal interface material (TIM) layer 170 on the package module 120, and attaching a package lid 130 to the outer molding material layer 327 over the TIM layer 170, wherein the package lid 130 may include a bottom lid portion 130B having a first coefficient of thermal expansion (CTE), and a top lid portion 130A attached to the bottom lid portion 130B and having a second CTE less than the first CTE.

In an embodiment, the method may further include forming the package lid 130, including forming a bonding layer 135 on one of the bottom lid portion 130B or the top lid portion 130A, pressing the other of the bottom lid portion 130B or the top lid portion 130A onto to the bonding layer 135. In an embodiment, the forming of the package lid 130 further may include patterning an upper surface of the bottom lid portion 130B and a lower surface of the top lid portion 130A, and the pressing of the other of the bottom lid portion 130B or the top lid portion 130A onto to the bonding layer 135 may include interlocking the patterned upper surface S130B of the bottom lid portion 130B and the patterned lower surface S130A of the top lid portion 130A. In an embodiment, the method may further include, after the attaching of the package module 120 to the package substrate 110 and before the forming of the outer molding material layer 327, forming a package underfill layer 119 between the package module 120 and the package substrate 110. In an embodiment, the method may further include forming an adhesive layer 160 on the outer molding material layer 327, wherein the attaching of the package lid 130 to the outer molding material layer 327 may include attaching the bottom lid portion 130B of the package lid 130 to the outer molding material layer 327 with the adhesive layer 160.

Referring again to FIGS. 1A-11, a semiconductor device may include a printed circuit board (PCB) 1103, a package structure 100 on the PCB 1103, including a package substrate 110, a package module 120 on the package substrate 110, an outer molding material layer 327 on the package substrate 110 around the package module 120, a thermal interface material (TIM) layer 170 on the package module 120, a package lid 130 on the TIM layer 170 and attached to the outer molding material layer 327, including a bottom lid portion 130B having a first coefficient of thermal expansion (CTE), and a top lid portion 130A attached to the bottom lid portion 130B and having a second CTE less than the first CTE. The semiconductor device 1100 may further include an upper TIM layer 1101 on the package structure 100, and a heat sink 1102 on the upper TIM layer 1101 and attached to the PCB 1103.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package module, comprising:
a lower redistribution layer (RDL) structure including a plurality of redistribution layers;
a lower molded portion on the lower RDL structure, the lower molded portion including:
a lower molding material layer on the lower RDL structure;
an interconnect die surrounded by the lower molding material layer; and
a plurality of through insulator vias (TIVs) in the lower molding material layer adjacent the interconnect die;
an upper RDL structure on the lower molded portion and electrically coupled to the interconnect die and the TIVs; and
an upper molded portion on the upper RDL structure, the upper molded portion including a plurality of semiconductor dies electrically coupled to the upper RDL structure.

2. The package module of claim 1, wherein the interconnect die comprises a local silicon interconnect (LSI) die including:
a bulk semiconductor portion on the lower RDL structure;
an interconnect portion including metal interconnects on the bulk semiconductor portion; and
bonding pads on an upper surface of the LSI die and electrically coupled to the metal interconnects.

3. The package module of claim 2, wherein the LSI die further comprises through vias in the bulk semiconductor portion, wherein the through vias electrically couple the metal interconnects in the interconnect portion to the redistribution layers in the lower RDL structure.

4. The package module of claim 1, wherein the interconnect die comprises a local redistribution interconnect (LRI) die including:
a bulk semiconductor portion on the lower RDL structure;
a redistribution portion including metal redistribution layers on the bulk semiconductor portion; and
bonding pads on an upper surface of the LRI die and electrically coupled to the metal redistribution layers.

5. The package module of claim 1, wherein the lower molded portion includes a local silicon interconnect (LSI) die and a local redistribution interconnect (LRI) die, and the plurality of semiconductor dies includes a first semiconductor die and a plurality of second semiconductor dies, wherein the LSI die interconnects the first semiconductor die to one or more of the second semiconductor dies, and the LRI die interconnects the first semiconductor die to one or more of the second semiconductor dies on an opposite side of the first semiconductor die.

6. The package module of claim 1, wherein the upper molded portion further comprises:
a package module underfill layer under and around each of the plurality of semiconductor dies; and
an upper molding material layer around the plurality of semiconductor dies, wherein an upper surface of the upper molding material layer is substantially coplanar with an upper surface of the plurality of semiconductor dies.

7. The package module of claim 1, wherein the plurality of semiconductor dies are connected to bonding pads on an upper surface of the upper RDL structure by microbumps.

8. The package module of claim 1, wherein an upper surface of the TIVs is substantially coplanar with an upper surface of bonding pads on the interconnect die and an upper surface of the lower molding material layer.

9. The package module of claim 1, further comprising a plurality of C4 bumps on a board-side surface of the lower RDL structure, wherein the C4 bumps are electrically coupled to the redistribution layers in the lower RDL structure.

10. A method of forming a package module, the method comprising:
forming a plurality of through insulator vias (TIVs) on a first carrier substrate;
placing an interconnect die on the first carrier substrate adjacent the TIVs;
forming a lower molding material layer on the first carrier substrate, the lower molding material layer surrounding the interconnect die and the TIVs;
planarizing the lower molding material layer to expose an upper surface of the interconnect die and an upper surface of the TIVs;
forming an upper redistribution layer (RDL) structure on the lower molding material layer, the upper RDL structure electrically coupled to the interconnect die and the TIVs; and
mounting a plurality of semiconductor dies on the upper RDL structure.

11. The method of claim 10, further comprising:
after the mounting of the plurality of semiconductor dies, forming a package module underfill layer under and around each of the plurality of semiconductor dies.

12. The method of claim 11, further comprising:
after the forming of the package module underfill layer, forming an upper molding material layer around the plurality of semiconductor dies; and
planarizing the upper molding material layer so that an upper surface of the upper molding material layer is substantially coplanar with an upper surface of the plurality of semiconductor dies.

13. The method of claim 12, further comprising:
after the planarizing of the upper molding material layer, attaching a second carrier substrate to the upper molding material layer;
detaching the first carrier substrate from the lower molding material layer; and
forming a lower RDL structure on the lower molding material layer.

14. The method of claim 13, further comprising:
forming a plurality of C4 bumps on a board-side surface of the lower RDL structure.

15. The method of claim 10, wherein placing of the interconnect die comprises placing a local silicon interconnect (LSI) die and a local redistribution interconnect (LRI) die on the first carrier substrate.

16. A package structure, comprising:
a package substrate;
a package module on the package substrate and electrically coupled to the package substrate, the package module comprising:
a lower redistribution layer (RDL) structure;
a lower molded portion on the lower RDL structure, the lower molded portion including a local silicon interconnect (LSI) die, a local redistribution interconnect (LRI) die, a lower molding material layer surrounding the LSI die and the LRI die, and a plurality of through insulator vias (TIVs) in the lower molding material layer;
an upper RDL structure on the lower molded portion; and
an upper molded portion on the upper RDL structure, the upper molded portion including a first semiconductor die and a plurality of second semiconductor dies adjacent the first semiconductor die, wherein the LSI die interconnects the first semiconductor die to at least one of the second semiconductor dies through the upper RDL structure; and
an outer molding material layer on the package substrate around the package module.

17. The package structure of claim 16, wherein the LRI die interconnects the first semiconductor die to at least one of the second semiconductor dies on an opposite side of the first semiconductor die from the at least one of the second semiconductor dies interconnected by the LSI die.

18. The package structure of claim 16, wherein the upper molded portion further comprises an upper molding material layer around the first semiconductor die and the plurality of second semiconductor dies, and an upper surface of the upper molding material layer is substantially coplanar with an upper surface of the first semiconductor die and an upper surface of the second semiconductor dies.

19. The package structure of claim 16, further comprising:
a package underfill layer between the package substrate and the package module; and
a plurality of C4 bumps connecting the lower RDL structure to the package substrate.

20. The package structure of claim 16, wherein the LSI die comprises:
a bulk semiconductor portion;
an interconnect portion including metal interconnects on the bulk semiconductor portion;
LSI bonding pads on an upper surface of the LSI die and electrically coupled to the redistribution layers in the upper RDL structure; and
through vias in the bulk semiconductor portion electrically coupling the metal interconnects to the redistribution layers in the lower RDL structure.
